(19) United States
(12) Patent Application Publication
(10) Pub. No.: US 2016/0272753 A1
(43) Pub. Date: Sep. 22, 2016

(54) CONJUGATED POLYMERS

(71) Applicant: MERCK PATENT GMBH, Darmstadt (DE)

(72) Inventors: Lana NANSON, Southampton (GB); Nicolas BLOUIN, Southampton (GB); Steven TIERNEY, Southampton (GB)

(73) Assignee: MERCK PATENT GMBH, Darmstadt (DE)

(21) Appl. No.: 15/034,572

(22) PCT Filed: Oct. 13, 2014
(86) PCT No.: PCT/EP2014/002761

§ 371 Date: May 5, 2016

(30) Foreign Application Priority Data
Nov. 6, 2013 (EP) 13005232.7

(51) Int. Cl. C08G 61/12; H01L 51/00

(52) U.S. Cl. CPC C08G 61/122; C08G 61/126; H01L 51/0036; H01L 51/0043; H01L 51/0094; H01L 51/0046; H01L 51/0047; C08G 2261/3241; C08G 2261/91; C08G 2261/3223; H01L 51/0566

(57) ABSTRACT

Disclosed are novel conjugated polymers containing one or more 3,4-dithia-7-sila-cyclopenta[a]pentalene based units and one or more pyrazino[2,3-g]quinoxaline based units, methods for their preparation and educts or intermediates used therein, polymer blends, mixtures and formulations containing them, the use of the polymers, polymer blends, mixtures and formulations as organic semiconductors in organic electronic (OE) devices, especially in organic photovoltaic (OPV) devices and organic photodetectors (OPD), and to OE, OPV and OPD devices containing these polymers, polymer blends, mixtures or formulations.

### TECHNICAL FIELD

The invention relates to novel conjugated polymers containing one or more 3,4-dithia-7-sila-cyclopenta[a]pentalene based units and one or more pyrazino[2,3-g]quinoxaline based units, to methods for their preparation and educts or intermediates used therein, to polymer blends, mixtures and formulations containing them, to the use of the polymers, polymer blends, mixtures and formulations as organic semiconductors in organic electronic (OE) devices, especially in organic photovoltaic (OPV) devices and organic photodetectors (OPD), and to OE, OPV and OPD devices comprising these polymers, polymer blends, mixtures or formulations.

### BACKGROUND

In recent years, there has been development of organic semiconducting (OSC) materials in order to produce more versatile, lower cost electronic devices. Such materials find application in a wide range of devices or apparatus, including organic field effect transistors (OFETs), organic light emitting diodes (OLEDs), organic photodetectors (OPDs), organic photovoltaic (OPV) cells, sensors, memory elements and logic circuits to name just a few. The organic semiconducting materials are typically present in the electronic device in the form of a thin layer, for example of between 50 and 300 nm thickness.

One particular area of importance is organic photovoltaics (OPV). Conjugated polymers have found use in OPVs as they allow devices to be manufactured by solution-processing techniques such as spin casting, dip coating or ink jet printing. Solution processing can be carried out cheaper and on a larger scale compared to the evaporative techniques used to make inorganic thin film devices. Currently, polymer based photovoltaic devices are achieving efficiencies above 8%.

However, the polymers for use in OPV or OPD devices that have been disclosed in prior art still leave room for further improvements, like a lower bandgap, better processability especially from solution, higher OPV cell efficiency, and higher stability.

Thus there is still a need for organic semiconducting (OSC) polymers which are easy to synthesize, especially by methods suitable for mass production, show good structural organization and film-forming properties, exhibit good electronic properties, especially a high charge carrier mobility, a good processibility, especially a high solubility in organic solvents, and high stability in air. Especially for use in OPV cells, there is a need for OSC materials having a low bandgap, which enable improved light harvesting by the photoactive layer and can lead to higher cell efficiencies, compared to the polymers from prior art.

It was an aim of the present invention to provide compounds for use as organic semiconducting materials that are easy to synthesize, especially by methods suitable for mass production, and do especially show good processibility, high stability, good solubility in organic solvents, high charge carrier mobility, and a low bandgap. Another aim of the invention was to extend the pool of OSC materials available to the expert. Other aims of the present invention are immediately evident to the expert from the following detailed description.

The inventors of the present invention have found that one or more of the above aims can be achieved by providing conjugated polymers as disclosed and claimed hereinafter. These polymers comprise a 3,4-dithia-7-sila-cyclopenta[a]pentalene unit (hereinafter also referred to as “silacyclopentadithiophene”), or a carbon, nitrogen or germanium derivative thereof, which is substituted in 7-position, and further comprise a pyrazino[2,3-g]quinoxaline unit (hereinafter also referred to as “bisquinoxaline”) which is substituted in one or more of the 2-, 3-, 7- and 8-positions.

These polymers are especially suitable for use in photovoltaic applications. By the incorporation of the electron-donating silacyclopentadithiophene unit and the electron-accepting bisquinoxaline unit into a co-polymer i.e. a “donor-acceptor” polymer, a reduction of the bandgap can be achieved, which enables improved light harvesting properties in bulk heterojunction (BHJ) photovoltaic devices. By alteration of the electron-accepting unit, the copolymer's solubility and electronic properties can be further modified.

Conjugated polymers and co-polymers based upon 7,7-bisalkyl-silacyclopentadithiophene have been disclosed in WO 2010/016986 A1. However, co-polymers with bisquinoxaline as claimed hereinafter are not disclosed.

WO 2010/022058 A1 discloses donor-acceptor co-polymers comprising a silacyclopentadithiophene unit as donor unit and an acceptor unit. A specific co-polymer is disclosed where the acceptor unit is an unsubstituted benzothiadiazole unit, yielding EQEs of approx. 2% at 950 nm. However, since the benzothiadiazole unit is lacking in any solubilising groups the resultant co-polymer was found to have limited solubility. WO 2010/022058 A1 further discloses that the acceptor unit can be selected from a list of heteroaromatic groups including, amongst others, also an unsubstituted bisquinoxaline unit. However, no specific examples for such a unit are given. Also, there is no disclosure of a substituted bisquinoxaline unit or of a co-polymer comprising it.

F. Zhang et al., J. Mater. Chem., 2008, 18, 5468-5474 discloses a copolymer comprising a 5,10-bisthiophene-2, 3, 7, 8-tetraphenyl-bisquinoxaline unit and a 9,9-bisalkylfluorene unit.

A. P. Zoombelt et al., J. Mater. Chem., 2009, 19, 5336-5342 discloses a polymer comprising a 2,3,7,8-tetrasubstituted bisquinoxaline unit flanked by two thiophene units.

WO 2010/114116 A1 discloses a bisquinoxaline unit, but does only exemplify unsubstituted and alkyne-substituted thiophene-flanked bisquinoxaline co-carbazole polymers.

Conjugated polymers as disclosed in the present invention and as claimed hereinafter have not been disclosed or suggested in prior art so far.

### SUMMARY

The invention relates to a conjugated polymer comprising one or more divalent units of formula I and one or more divalent units of formula II

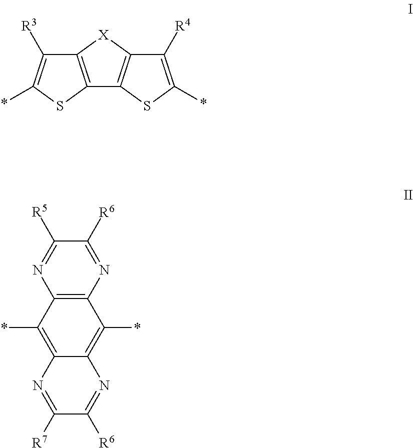

wherein X is SiR¹R², CR¹R², NR¹ or GeR¹R², and R¹⁻⁸ independently of each other denote H or a carbyl or hydrocarbyl group with 1 to 40 C atoms that is optionally substituted, wherein at least one of R¹ and R² is different from H and at last one of R⁵ to R⁸ is different from H.

The invention further relates to a formulation comprising one or more polymers comprising one or more units of formula I and one or more units of formula II and one or more solvents, preferably selected from organic solvents.

The invention further relates to conjugated polymers containing one or more units of formula I, or one or more units of formula II, and further containing one or more units selected from arylene and heteroarylene units that are optionally substituted.

The invention further relates to monomers containing one or more units of formula I and one or more units of formula II, and further containing one or more reactive groups which can be reacted to form a conjugated polymer as described above and below.

The invention further relates to the use of the polymers according to the present invention as electron donor or p-type semiconductor.

The invention further relates to the use of the polymers according to the present invention as electron donor component in a semiconducting material, formulation, polymer blend, device or component of a device.

The invention further relates to a semiconducting material, formulation, polymer blend, device or component of a device comprising a polymer according to the present invention as electron donor component, and preferably further comprising one or more compounds or polymers having electron acceptor properties.

The invention further relates to a mixture or polymer blend comprising one or more polymers according to the present invention and one or more additional compounds which are preferably selected from compounds having one or more of semiconducting, charge transport, hole or electron transport, hole or electron blocking, electrically conducting, photoconducting or light emitting properties.

The invention further relates to a mixture or polymer blend as described above and below, which comprises one or more polymers of the present invention and one or more n-type organic semiconductor compounds, preferably selected from fullerenes or substituted fullerenes.

The invention further relates to a formulation comprising one or more polymers, formulations, mixtures or polymer blends according to the present invention and optionally one or more solvents, preferably selected from organic solvents.

The invention further relates to the use of a polymer, formulation, mixture or polymer blend of the present invention as charge transport, semiconducting, electrically conducting, photoconducting or light emitting material, or in an optical, electrooptical, electronic, electroluminescent or photoluminescent device, or in a component of such a device or in an assembly comprising such a device or component.

The invention further relates to a charge transport, semiconducting, electrically conducting, photoconducting or light emitting material comprising a polymer, formulation, mixture or polymer blend according to the present invention.

The invention further relates to an optical, electrooptical, electronic, electroluminescent or photoluminescent device, or a component thereof, or an assembly comprising it, which comprises a polymer, formulation, mixture or polymer blend, or comprises a charge transport, semiconducting, electrically conducting, photoconducting or light emitting material, according to the present invention.

The optical, electrooptical, electronic, electroluminescent and photoluminescent devices include, without limitation, organic field effect transistors (OFET), organic thin film transistors (OTFT), organic light emitting diodes (OLED), organic light emitting transistors (OLET), organic photovoltaic devices (OPV), organic photodetectors (OPD), organic solar cells, laser diodes, Schottky diodes, photoconductors and photodetectors.

The components of the above devices include, without limitation, charge injection layers, charge transport layers, interlayers, planarising layers, antistatic films, polymer electrolyte membranes (PEM), conducting substrates and conducting patterns.

The assemblies comprising such devices or components include, without limitation, integrated circuits (IC), radio frequency identification (RFID) tags or security markings or security devices containing them, flat panel displays or backlights thereof, electrophotographic devices, electrophotographic recording devices, organic memory devices, sensor devices, biosensors and biochips.

In addition the compounds, polymers, formulations, mixtures or polymer blends of the present invention can be used as electrode materials in batteries and in components or devices for detecting and discriminating DNA sequences.

### BRIEF DESCRIPTION OF THE DRAWINGS

FIGS. 1, 2 and 3 show the J-V curve for an OPD device of Example 4, comprising a blend of Polymers 1, 2 and 3 of Examples 1, 2 and 3, and PC₇₀BM.

### DETAILED DESCRIPTION

The polymers of the present invention are easy to synthesize and exhibit advantageous properties. They show good processability for the device manufacture process, high solubility in organic solvents, and are especially suitable for large scale production using solution processing methods. At the same time, they show low bandgaps, high charge carrier mobilities, high external quantum efficiencies in BHJ solar cells, good morphology when used in p/n-type blends e.g. with fullerenes, high oxidative stability, and a long lifetime in electronic devices, and are promising materials for organic electronic OE devices, especially for OPV and OPD devices with high power conversion efficiency.

In particular, compared to previously disclosed silacyclopentadithiophene or bisquinoxaline based polymers, the polymers of the present invention demonstrate the following improved properties:
i) The lack of spacer units between the silacyclopentadithiophene donor and the bisquinoxaline increases the HOMO level and decreases the bandgap of the polymer.
ii) The use of the silacyclopentadithiophene unit can be thought of as an alternative to the bis-thiophene units previously reported, however the use of the silacyclopentadithiophene unit offers additional benefits, such as pinning the backbone into a planar configuration, thus reducing the degrees of rotation, hence improving conjugation along the backbone and decreasing the bandgap of the polymer.
iii) The use of additional monomer units provides a tool to fine-tune the energy levels of the polymer, thus reducing the energy loss in the electron transfer process between the polymer and the n-type material (i.e. fullerene, graphene, metal oxide) in the active layer.
iv) Additional variation of the R¹-R⁸ substituents allows further energy level fine tuning, thus also reducing the energy loss in the electron transfer process between the polymer and the n-type material (i.e. fullerene, graphene, metal oxide) in the active layer.
v) Use of additional monomers to yield random and statistical block co-polymers provides additional disorder, leading to improved entropy of solution, especially in non-halogenated solvents.
vi) Additional variation of the R⁵-R⁸ substituents on the bisquinoxaline unit allows modulation of the polymer solubility compared to co-polymers of silacyclopentadithiophene and benzothiadiazole units as disclosed in prior art.
vii) Additional thiophene units between the silacyclopentadithiophene and bisquinoxaline units lead to decreased solubility of the resultant polymer, elimination of these groups therefore yields a more soluble polymer.

The synthesis of the units of formula I and II, their functional derivatives, compounds, homopolymers, and co-polymers can be achieved based on methods that are known to the skilled person and described in the literature, as will be further illustrated herein.

As used herein, the term “polymer” will be understood to mean a molecule of high relative molecular mass, the structure of which essentially comprises the multiple repetition of units derived, actually or conceptually, from molecules of low relative molecular mass (Pure Appl. Chem., 1996, 68, 2291). The term “oligomer” will be understood to mean a molecule of intermediate relative molecular mass, the structure of which essentially comprises a small plurality of units derived, actually or conceptually, from molecules of lower relative molecular mass (Pure Appl. Chem., 1996, 68, 2291). In a preferred meaning as used herein present invention a polymer will be understood to mean a compound having >1, i.e. at least 2 repeat units, preferably ≧5 repeat units, and an oligomer will be understood to mean a compound with >1 and <10, preferably <5, repeat units.

Further, as used herein, the term “polymer” will be understood to mean a molecule that encompasses a backbone (also referred to as “main chain”) of one or more distinct types of repeat units (the smallest constitutional unit of the molecule) and is inclusive of the commonly known terms “oligomer”, “copolymer”, “homopolymer” and the like. Further, it will be understood that the term polymer is inclusive of, in addition to the polymer itself, residues from initiators, catalysts and other elements attendant to the synthesis of such a polymer, where such residues are understood as not being covalently incorporated thereto. Further, such residues and other elements, while normally removed during post polymerization purification processes, are typically mixed or co-mingled with the polymer such that they generally remain with the polymer when it is transferred between vessels or between solvents or dispersion media.

As used herein, in a formula showing a polymer or a repeat unit, an asterisk (*) will be understood to mean a chemical linkage to an adjacent unit or to a terminal group in the polymer backbone. In a ring, like for example a benzene or thiophene ring, an asterisk (*) will be understood to mean a C atom that is fused to an adjacent ring.

As used herein, the terms “repeat unit”, “repeating unit” and “monomeric unit” are used interchangeably and will be understood to mean the constitutional repeating unit (CRU), which is the smallest constitutional unit the repetition of which constitutes a regular macromolecule, a regular oligomer molecule, a regular block or a regular chain (Pure Appl. Chem., 1996, 68, 2291). As further used herein, the term “unit” will be understood to mean a structural unit which can be a repeating unit on its own, or can together with other units form a constitutional repeating unit.

As used herein, a “terminal group” will be understood to mean a group that terminates a polymer backbone. The expression “in terminal position in the backbone” will be understood to mean a divalent unit or repeat unit that is linked at one side to such a terminal group and at the other side to another repeat unit. Such terminal groups include endcap groups, or reactive groups that are attached to a monomer forming the polymer backbone which did not participate in the polymerisation reaction, like for example a reactive group having the meaning of R^{R1} or R^{R2} as defined below.

As used herein, the term “endcap group” will be understood to mean a group that is attached to, or replacing, a terminal group of the polymer backbone. The endcap group can be introduced into the polymer by an endcapping process. Endcapping can be carried out for example by reacting the terminal groups of the polymer backbone with a monofunctional compound (“endcapper”) like for example an alkyl- or arylhalide, an alkyl- or arylstannane or an alkyl- or arylboronate. The endcapper can be added for example after the polymerisation reaction. Alternatively the endcapper can be added in situ to the reaction mixture before or during the polymerisation reaction. In situ addition of an endcapper can also be used to terminate the polymerisation reaction and thus control the molecular weight of the forming polymer. Typical endcap groups are for example H, phenyl and lower alkyl.

As used herein, the term “small molecule” will be understood to mean a monomeric compound which typically does not contain a reactive group by which it can be reacted to form a polymer, and which is designated to be used in monomeric form. In contrast thereto, the term “monomer” unless stated otherwise will be understood to mean a monomeric compound that carries one or more reactive functional groups by which it can be reacted to form a polymer.

As used herein, the terms “donor” or “donating” and “acceptor” or “accepting” will be understood to mean an electron donor or electron acceptor, respectively. “Electron donor” will be understood to mean a chemical entity that donates electrons to another compound or another group of atoms of a compound. “Electron acceptor” will be understood to mean a chemical entity that accepts electrons transferred to it from another compound or another group of atoms of a compound. See also International Union of Pure and Applied Chemistry, Compendium of Chemical Technology, Gold Book, Version 2.3.2, 19, Aug. 2012, pages 477 and 480.

As used herein, the term “n-type” or “n-type semiconductor” will be understood to mean an extrinsic semiconductor in which the conduction electron density is in excess of the mobile hole density, and the term “p-type” or “p-type semiconductor” will be understood to mean an extrinsic semiconductor in which mobile hole density is in excess of the conduction electron density (see also, J. Thewlis, Concise Dictionary of Physics, Pergamon Press, Oxford, 1973).

As used herein, the term “leaving group” will be understood to mean an atom or group (which may be charged or uncharged) that becomes detached from an atom in what is considered to be the residual or main part of the molecule taking part in a specified reaction (see also Pure Appl. Chem., 1994, 66, 1134).

As used herein, the term “conjugated” will be understood to mean a compound (for example a polymer) that contains mainly C atoms with sp²-hybridisation (or optionally also sp-hybridisation), and wherein these C atoms may also be replaced by hetero atoms. In the simplest case this is for example a compound with alternating C—C single and double (or triple) bonds, but is also inclusive of compounds with aromatic units like for example 1,4-phenylene. The term “mainly” in this connection will be understood to mean that a compound with naturally (spontaneously) occurring defects, or with defects included by design, which may lead to interruption of the conjugation, is still regarded as a conjugated compound.

As used herein, unless stated otherwise the molecular weight is given as the number average molecular weight Mₙ or weight average molecular weight M_{W}, which is determined by gel permeation chromatography (GPC) against polystyrene standards in eluent solvents such as tetrahydrofuran, trichloromethane (TCM, chloroform), chlorobenzene or 1,2,4-trichlorobenzene. Unless stated otherwise, 1,2,4-trichlorobenzene is used as solvent. The degree of polymerization, also referred to as total number of repeat units, n, will be understood to mean the number average degree of polymerization given as n=Mₙ/M_{U}, wherein Mₙ is the number average molecular weight and M_{U} is the molecular weight of the single repeat unit, see J. M. G. Cowie, Polymers: Chemistry & Physics of Modern Materials, Blackie, Glasgow, 1991.

As used herein, the term “carbyl group” will be understood to mean any monovalent or multivalent organic moiety which comprises at least one carbon atom either without any non-carbon atoms (like for example —C≡C—), or optionally combined with at least one non-carbon atom such as B, N, O, S, P, Si, Se, As, Te or Ge (for example carbonyl etc.).

As used herein, the term “hydrocarbyl group” will be understood to mean a carbyl group that does additionally contain one or more H atoms and optionally contains one or more hetero atoms like for example B, N, O, S, P, Si, Se, As, Te or Ge.

As used herein, the term “hetero atom” will be understood to mean an atom in an organic compound that is not a H- or C-atom, and preferably will be understood to mean B, N, O, S, P, Si, Se, As, Te or Ge.

A carbyl or hydrocarbyl group comprising a chain of 3 or more C atoms may be straight-chain, branched and/or cyclic, and may include spiro-connected and/or fused rings.

Preferred carbyl and hydrocarbyl groups include alkyl, alkoxy, alkylcarbonyl, alkoxycarbonyl, alkylcarbonyloxy and alkoxycarbonyloxy, each of which is optionally substituted and has 1 to 40, preferably 1 to 25, very preferably 1 to 18 C atoms, furthermore optionally substituted aryl or aryloxy having 5 to 40, preferably 5 to 25 C atoms, furthermore alkylaryloxy, arylcarbonyl, aryloxycarbonyl, arylcarbonyloxy and aryloxycarbonyloxy, each of which is optionally substituted and has 6 to 40, preferably 7 to 40 C atoms, wherein all these groups do optionally contain one or more hetero atoms, preferably selected from B, N, O, S, P, Si, Se, As, Te and Ge.

Further preferred carbyl and hydrocarbyl group include for example: a C₁-C₄₀ alkyl group, a C₁-C₄₀ fluoroalkyl group, a C₁-C₄₀ alkoxy or oxaalkyl group, a C₂-C₄₀ alkenyl group, a C₂-C₄₀ alkynyl group, a C₃-C₄₀ allyl group, a C₄-C₄₀ alkyldienyl group, a C₄-C₄₀ polyenyl group, a C₂-C₄₀ ketone group, a C₂-C₄₀ ester group, a C₅-C₁₈ aryl group, a C₆-C₄₀ alkylaryl group, a C₆-C₄₀ arylalkyl group, a C₄-C₄₀ cycloalkyl group, a C₄-C₄₀ cycloalkenyl group, and the like. Preferred among the foregoing groups are a C₁-C₂₀ alkyl group, a C₁-C₂₀ fluoroalkyl group, a C₂-C₂₀ alkenyl group, a C₂-C₂₀ alkynyl group, a C₃-C₂₀ allyl group, a C₄-C₂₀ alkyldienyl group, a C₂-C₂₀ ketone group, a C₂-C₂₀ ester group, a C₆-C₁₂ aryl group, and a C₄-C₂₀ polyenyl group, respectively.

Also included are combinations of groups having carbon atoms and groups having hetero atoms, like e.g. an alkynyl group, preferably ethynyl, that is substituted with a silyl group, preferably a trialkylsilyl group.

The carbyl or hydrocarbyl group may be an acyclic group or a cyclic group. Where the carbyl or hydrocarbyl group is an acyclic group, it may be straight-chain or branched. Where the carbyl or hydrocarbyl group is a cyclic group, it may be a non-aromatic carbocyclic or heterocyclic group, or an aryl or heteroaryl group.

A non-aromatic carbocyclic group as referred to above and below is saturated or unsaturated and preferably has 4 to 30 ring C atoms. A non-aromatic heterocyclic group as referred to above and below preferably has 4 to 30 ring C atoms, wherein one or more of the C ring atoms are optionally replaced by a hetero atom, preferably selected from N, O, S, Si and Se, or by a —S(O)— or —S(O)₂— group. The non-aromatic carbo- and heterocyclic groups are mono- or polycyclic, may also contain fused rings, preferably contain 1, 2, 3 or 4 fused or unfused rings, and are optionally substituted with one or more groups L, wherein

L is selected from halogen, —CN, —NC, —NCO, —NCS, —OCN, —SCN, —C(═O)NR⁰R⁰⁰, —C(═O)X⁰, —C(═O)R⁰, —NH₂, —NR⁰R⁰⁰, —SH, —SR⁰, —SO₃H, —SO₂R⁰, —OH, —NO₂, —CF₃, —SF₅, optionally substituted silyl, or carbyl or hydrocarbyl with 1 to 40 C atoms that is optionally substituted and optionally comprises one or more hetero atoms, and is preferably alkyl, alkoxy, thioalkyl, alkylcarbonyl, alkoxycarbonyl or alkoxycarbonyloxy with 1 to 20 C atoms that is optionally fluorinated,
X⁰ is halogen, preferably F, Cl or Br, and
R⁰, R⁰⁰ independently of each other denote H or an optionally substituted carbyl or hydrocarbyl group with 1 to 40 C atoms, and preferably denote H or alkyl with 1 to 12 C atoms.

Preferred substituents L are selected from halogen, most preferably F, or alkyl, alkoxy, oxaalkyl, thioalkyl, fluoroalkyl and fluoroalkoxy with 1 to 16 C atoms, or alkenyl or alkynyl with 2 to 16 C atoms.

Preferred non-aromatic carbocyclic or heterocyclic groups are tetrahydrofuran, indane, pyran, pyrrolidine, piperidine, cyclopentane, cyclohexane, cycloheptane, cyclopentanone, cyclohexanone, dihydro-furan-2-one, tetrahydro-pyran-2-one and oxepan-2-one.

An aryl group as referred to above and below preferably has 4 to 30 ring C atoms, is mono- or polycyclic and may also contain fused rings, preferably contains 1, 2, 3 or 4 fused or unfused rings, and is optionally substituted with one or more groups L as defined above.

A heteroaryl group as referred to above and below preferably has 4 to 30 ring C atoms, wherein one or more of the C ring atoms are replaced by a hetero atom, preferably selected from N, O, S, Si and Se, is mono- or polycyclic and may also contain fused rings, preferably contains 1, 2, 3 or 4 fused or unfused rings, and is optionally substituted with one or more groups L as defined above.

As used herein, “arylene” will be understood to mean a divalent aryl group, and “heteroarylene” will be understood to mean a divalent heteroaryl group, including all preferred meanings of aryl and heteroaryl as given above and below.

Preferred aryl and heteroaryl groups are phenyl in which, in addition, one or more CH groups may be replaced by N, naphthalene, thiophene, selenophene, thienothiophene, dithienothiophene, fluorene and oxazole, all of which can be unsubstituted, mono- or polysubstituted with L as defined above. Very preferred rings are selected from phenyl, pyrrole, preferably N-pyrrole, furan, pyridine, preferably 2- or 3-pyridine, pyrimidine, pyridazine, pyrazine, triazole, tetrazole, pyrazole, imidazole, isothiazole, thiazole, thiadiazole, isoxazole, oxazole, oxadiazole, thiophene, preferably 2-thiophene, selenophene, preferably 2-selenophene, thieno[3,2-b]thiophene, thieno[2,3-b]thiophene, furo[3,2-b]furan, furo[2,3-b]furan, seleno[3,2-b]selenophene, seleno[2,3-b]selenophene, thieno[3,2-b]selenophene, thieno[3,2-b]furan, indole, isoindole, benzo[b]furan, benzo[b]thiophene, benzo[1,2-b;4,5-b′]dithiophene, benzo[2,1-b;3,4-b′]dithiophene, quinole, 2-methylquinole, isoquinole, quinoxaline, quinazoline, benzotriazole, benzimidazole, benzothiazole, benzisothiazole, benzisoxazole, benzoxadiazole, benzoxazole, benzothiadiazole, 4H-cyclopenta[2,1-b;3,4-b′]dithiophene, 7H-3,4-dithia-7-sila-cyclopenta[a]pentalene, all of which can be unsubstituted, mono- or polysubstituted with L as defined above. Further examples of aryl and heteroaryl groups are those selected from the groups shown hereinafter.

An alkyl group or an alkoxy group, i.e., where the terminal CH₂ group is replaced by —O—, can be straight-chain or branched. It is preferably straight-chain, has 2, 3, 4, 5, 6, 7, 8, 10, 12, 14, 16 or 18 carbon atoms and accordingly is preferably ethyl, propyl, butyl, pentyl, hexyl, heptyl, octyl, decyl, dodecyl, tetradecyl, hexadecyl, octadecyl, ethoxy, propoxy, butoxy, pentoxy, hexoxy, heptoxy, octoxy, decoxy, dodecoxy, tetradecoxy, hexadecoxy, octadecoxy, furthermore methyl, nonyl, undecyl, tridecyl, pentadecyl, heptadecyl, nonadecyl, methoxy, nonoxy, undecoxy, tridecoxy, pentadecoxy or heptadecoxy, for example.

An alkenyl group, i.e., wherein one or more CH₂ groups are replaced by —CH═CH— can be straight-chain or branched. It is preferably straight-chain, has 2 to 10 C atoms and accordingly is preferably vinyl, prop-1-, or prop-2-enyl, but-1-, 2- or but-3-enyl, pent-1-, 2-, 3- or pent-4-enyl, hex-1-, 2-, 3-, 4- or hex-5-enyl, hept-1-, 2-, 3-, 4-, 5- or hept-6-enyl, oct-1-, 2-, 3-, 4-, 5-, 6- or oct-7-enyl, non-1-, 2-, 3-, 4-, 5-, 6-, 7- or non-8-enyl, dec-1-, 2-, 3-, 4-, 5-, 6-, 7-, 8- or dec-9-enyl.

Especially preferred alkenyl groups are C₂-C₇-1E-alkenyl, C₄-C₇-3E-alkenyl, C₅-C₇-4-alkenyl, C₆-C₇-5-alkenyl and C₇-6-alkenyl, in particular C₂-C₇-1E-alkenyl, C₄-C₇-3E-alkenyl and C₅-C₇-4-alkenyl. Examples for particularly preferred alkenyl groups are vinyl, 1E-propenyl, 1E-butenyl, 1E-pentenyl, 1E-hexenyl, 1E-heptenyl, 3-butenyl, 3E-pentenyl, 3E-hexenyl, 3E-heptenyl, 4-pentenyl, 4Z-hexenyl, 4E-hexenyl, 4Z-heptenyl, 5-hexenyl, 6-heptenyl and the like. Groups having up to 5 C atoms are generally preferred.

An oxaalkyl group, i.e., where one CH₂ group is replaced by —O—, is preferably straight-chain 2-oxapropyl (=methoxymethyl), 2- (=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example.

In an alkyl group wherein one CH₂ group is replaced by —O— and one CH₂ group is replaced by —C(O)—, these radicals are preferably neighboured. Accordingly these radicals together form a carbonyloxy group —C(O)—O— or an oxycarbonyl group —O—C(O)—. Preferably this group is straight-chain and has 2 to 6 C atoms. It is accordingly preferably acetyloxy, propionyloxy, butyryloxy, pentanoyloxy, hexanoyloxy, acetyloxymethyl, propionyloxymethyl, butyryloxymethyl, pentanoyloxymethyl, 2-acetyloxyethyl, 2-propionyloxyethyl, 2-butyryloxyethyl, 3-acetyloxypropyl, 3-propionyloxypropyl, 4-acetyloxybutyl, methoxycarbonyl, ethoxycarbonyl, propoxycarbonyl, butoxycarbonyl, pentoxycarbonyl, methoxycarbonylmethyl, ethoxycarbonylmethyl, propoxycarbonylmethyl, butoxycarbonylmethyl, 2-(methoxycarbonyl)ethyl, 2-(ethoxycarbonyl)ethyl, 2-(propoxycarbonyl)ethyl, 3-(methoxycarbonyl)propyl, 3-(ethoxycarbonyl)propyl, 4-(methoxycarbonyl)-butyl.

An alkyl group wherein two or more CH₂ groups are replaced by —O— and/or —C(O)O— can be straight-chain or branched. It is preferably straight-chain and has 3 to 20 C atoms. Accordingly it is preferably bis-carboxy-methyl, 2,2-bis-carboxy-ethyl, 3,3-bis-carboxy-propyl, 4,4-bis-carboxy-butyl, 5,5-bis-carboxy-pentyl, 6,6-bis-carboxy-hexyl, 7,7-bis-carboxy-heptyl, 8,8-bis-carboxy-octyl, 9,9-bis-carboxy-nonyl, 10,10-bis-carboxy-decyl, bis-(methoxycarbonyl)-methyl, 2,2-bis-(methoxycarbonyl)-ethyl, 3,3-bis-(methoxycarbonyl)-propyl, 4,4-bis-(methoxycarbonyl)-butyl, 5,5-bis-(methoxycarbonyl)-pentyl, 6,6-bis-(methoxycarbonyl)-hexyl, 7,7-bis-(methoxycarbonyl)-heptyl, 8,8-bis-(methoxycarbonyl)-octyl, bis-(ethoxycarbonyl)-methyl, 2,2-bis-(ethoxycarbonyl)-ethyl, 3,3-bis-(ethoxycarbonyl)-propyl, 4,4-bis-(ethoxycarbonyl)-butyl, 5,5-bis-(ethoxycarbonyl)-hexyl.

A thioalkyl group, i.e., where one CH₂ group is replaced by —S—, is preferably straight-chain thiomethyl (—SCH₃), 1-thioethyl (—SCH₂CH₃), 1-thiopropyl (=—SCH₂CH₂CH₃), 1-(thiobutyl), 1-(thiopentyl), 1-(thiohexyl), 1-(thioheptyl), 1-(thiooctyl), 1-(thiononyl), 1-(thiodecyl), 1-(thioundecyl), 1-(thiododecyl), 1-(thiotetradecyl), 1-(thiohexadecyl) or 1-(thiooctadecyl) wherein preferably the CH₂ group adjacent to the sp² hybridised vinyl carbon atom is replaced.

A fluoroalkyl group is perfluoroalkyl CᵢF₂ᵢ₊₁, wherein i is an integer from 1 to 15, in particular CF₃, C₂F₅, C₃F₇, C₄F₉, C₅F₁₁, C₆F₁₃, C₇F₁₅, C₈F₁₇, C₁₀F₂₁, C₁₂F₂₅, C₁₄F₂₉, C₁₆F₃₃ or C₁₈F₃₅, very preferably C₆F₁₃, or partially fluorinated alkyl with 1 to 15 C atoms, in particular 1,1-difluoroalkyl, all of which are straight-chain or branched.

Alkyl, alkoxy, alkenyl, oxaalkyl, thioalkyl, carbonyl and carbonyloxy groups can be achiral or chiral groups. Particularly preferred chiral groups are 2-butyl (=1-methylpropyl), 2-methylbutyl, 2-methylpentyl, 3-methylpentyl, 2-ethylhexyl, 2-propylpentyl, 2-butyloctyl, 2-hexyldecyl, 2-octyldodecyl, 7-decylnonadecyl, in particular 2-methylbutyl, 2-methylbutoxy, 2-methylpentoxy, 3-methylpentoxy, 2-ethyl-hexoxy, 2-butyloctoxyo, 2-hexyldecoxy, 2-octyldodecoxy, 1-methylhexoxy, 2-octyloxy, 2-oxa-3-methylbutyl, 3-oxa-4-methyl-pentyl, 4-methylhexyl, 2-hexyl, 2-octyl, 2-nonyl, 2-decyl, 2-dodecyl, 6-meth-oxyoctoxy, 6-methyloctoxy, 6-methyloctanoyloxy, 5-methylheptyloxy-carbonyl, 2-methylbutyryloxy, 3-methylvaleroyloxy, 4-methylhexanoyloxy, 2-chloropropionyloxy, 2-chloro-3-methylbutyryloxy, 2-chloro-4-methyl-valeryl-oxy, 2-chloro-3-methylvaleryloxy, 2-methyl-3-oxapentyl, 2-methyl-3-oxa-hexyl, 1-methoxypropyl-2-oxy, 1-ethoxypropyl-2-oxy, 1-propoxypropyl-2-oxy, 1-butoxypropyl-2-oxy, 2-fluorooctyloxy, 2-fluorodecyloxy, 1,1,1-trifluoro-2-octyloxy, 1,1,1-trifluoro-2-octyl, 2-fluoromethyloctyloxy for example. Very preferred are 2-ethylhexyl, 2-butyloctyl, 2-hexyldecyl, 2-octyldodecyl, 2-hexyl, 2-octyl, 2-octyloxy, 1,1,1-trifluoro-2-hexyl, 1,1,1-trifluoro-2-octyl and 1,1,1-trifluoro-2-octyloxy.

Preferred achiral branched groups are isopropyl, isobutyl (=methylpropyl), isopentyl (=3-methylbutyl), tert. butyl, isopropoxy, 2-methyl-propoxy and 3-methylbutoxy.

In a preferred embodiment, the alkyl groups are independently of each other selected from primary, secondary or tertiary alkyl or alkoxy with 1 to 30 C atoms, wherein one or more H atoms are optionally replaced by F, or aryl, aryloxy, heteroaryl or heteroaryloxy that is optionally alkylated or alkoxylated and has 4 to 30 ring atoms. Very preferred groups of this type are selected from the group consisting of the following formulae

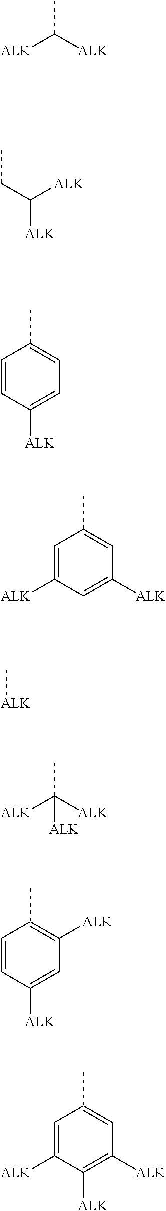

wherein “ALK” denotes optionally fluorinated, preferably linear, alkyl or alkoxy with 1 to 20, preferably 1 to 12 C-atoms, in case of tertiary groups very preferably 1 to 9 C atoms, and the dashed line denotes the link to the ring to which these groups are attached. Especially preferred among these groups are those wherein all ALK subgroups are identical.

As used herein, “halogen” or “Hal” includes F, Cl, Br or I, preferably F, Cl or Br.

As used herein, —CO—, —C(═O)— and —C(O)— will be understood to mean a carbonyl group, i.e. a group having the structure

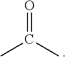

Above and below, Y¹ and Y² are independently of each other H, F, Cl or CN.

Above and below, R⁰ and R⁰⁰ are independently of each other H or an optionally substituted carbyl or hydrocarbyl group with 1 to 40 C atoms, and preferably denote H or alkyl with 1 to 12 C-atoms.

Preferred units of formula I are those wherein X is SiR¹R².

Further preferred units of formula I are those wherein R¹ and R² are different from H.

Further preferred units of formula I are those wherein R³ and R⁴ are H.

Further preferred units of formula I are those wherein R¹ and R² are selected from the group consisting of straight-chain or branched alkyl, alkoxy or sulfanylalkyl with 1 to 30 C atoms, and straight-chain or branched alkylcarbonyl, alkylcarbonyloxy or alkyloxycarbonyl with 2 to 30 C atoms, each of the aforementioned groups being unsubstituted or substituted by one or more F atoms, especially those wherein R³ and R⁴ are H.

Further preferred units of formula I are those wherein R¹ and R² are selected from the group consisting of aryl, heteroaryl, aryloxy and heteroaryloxy, each of which is optionally fluorinated, alkylated or alkoxylated and has 4 to 30 ring atoms, especially those wherein R³ and R⁴ are H.

Further preferred units of formula I are those wherein R³ and/or R⁴ are selected from the group consisting of straight-chain or branched alkyl, alkoxy or sulfanylalkyl with 1 to 30 C atoms, straight-chain or branched alkylcarbonyl, alkylcarbonyloxy or alkyloxycarbonyl with 2 to 30 C atoms, each of the aforementioned groups being unsubstituted or substituted by one or more F atoms, and aryl, heteroaryl, aryloxy or heteroaryloxy, each of which is optionally fluorinated, alkylated or alkoxylated and has 4 to 30 ring atoms.

Further preferred units of formula I are those wherein R³ and/or R⁴ are selected from the group consisting of aryl, heteroaryl, aryloxy and heteroaryloxy, each of which is optionally fluorinated, alkylated or alkoxylated and has 4 to 30 ring atoms, especially those wherein R¹ and R² are H.

Preferred units of formula II are those wherein R⁵, R⁶, R⁷ and R⁸ are different from H.

Further preferred units of formula II are those wherein R⁵, R⁶, R⁷ and R⁸ are selected from the group consisting of straight-chain or branched alkyl, alkoxy or sulfanylalkyl with 1 to 30 C atoms, and straight-chain or branched alkylcarbonyl, alkylcarbonyloxy or alkyloxycarbonyl with 2 to 30 C atoms, each of the aforementioned groups being unsubstituted or substituted by one or more F atoms.

Further preferred units of formula II are those wherein R⁵, R⁶, R⁷ and R⁸ are selected from the group consisting of aryl, heteroaryl, aryloxy and heteroaryloxy, each of which is optionally fluorinated, alkylated or alkoxylated and has 4 to 30 ring atoms.

In the case one or more of R¹ to R⁸ is an aryl(oxy) or heteroaryl(oxy) group, it is preferably selected from phenyl, pyrrole, furan, pyridine, thiazole, thiophene, thieno[3,2-b]thiophene or thieno[2,3-b]thiophene, each of which is optionally fluorinated, alkylated or alkoxylated.

In the case one or more of R¹ to R⁸ is an aryl(oxy) or heteroaryl(oxy) group that is alkylated or alkoxylated, this preferably means that it is substituted with one or more alkyl or alkoxy groups having from 1 to 20 C-atoms and being straight-chain or branched and wherein one or more H atoms are optionally substituted by an F atom.

Preferred polymers according to the present invention comprise, in addition to the units of formula I and II, one or more repeating units selected from arylene or heteroarylene groups with 5 to 30 ring atoms that are optionally substituted, preferably by one or more groups R^{S}, wherein
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —C(O)OR⁰, —NH₂, —NR⁰R⁰⁰, —SH, —SR⁰, —SO₃H, —SO₂R⁰, —OH, —NO₂, —CF₃, —SF₅, optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀ carbyl or hydrocarbyl, and preferably denote H or alkyl with 1 to 12 C-atoms,
X⁰ is halogen, preferably F, Cl or Br.

R^{S} preferably denotes, on each occurrence identically or differently, H, straight-chain, branched or cyclic alkyl with 1 to 30 C atoms, in which one or more CH₂ groups are optionally replaced by —O—, —S—, —C(O)—, —C(S)—, —C(O)—O—, —O—C(O)—, —NR⁰—, —SiR⁰R⁰⁰—, —CF₂—, —CHR⁰═CR⁰⁰—, —CY¹═CY²— or —C≡C— in such a manner that O and/or S atoms are not linked directly to one another, and in which one or more H atoms are optionally replaced by F, Cl, Br, I or CN, or denotes aryl, heteroaryl, aryloxy or heteroaryloxy with 4 to 20 ring atoms which is optionally substituted, preferably by halogen or by one or more of the aforementioned alkyl or cyclic alkyl groups.

The conjugated polymers according to the present invention are preferably selected of formula III:

*-[(D)_{d}-(A)ₐ-(Ar¹)_{b}—(Ar²)_{c}]ₙ—* III

wherein
D is a unit of formula I,
A is a unit of formula II,
Ar¹, Ar² independently of each other denote an arylene or heteroarylene group with 5 to 30 ring atoms that is optionally substituted, preferably by one or more groups R^{S} as defined above,
a, b, c, d are independently of each other 0, 1, 2 or 3, with at least one of a and d being different from 0 in at least one repeating unit,
n is an integer >1.

In a preferred embodiment, in the polymer of formula III, a and d are preferably 1 in all repeating units. In another preferred embodiment the polymer of formula III consists of repeating units wherein a is 1 and d is 0 and repeating units wherein a is 0 and d is 1.

Preferred polymers of formula III are selected of the following subformulae:

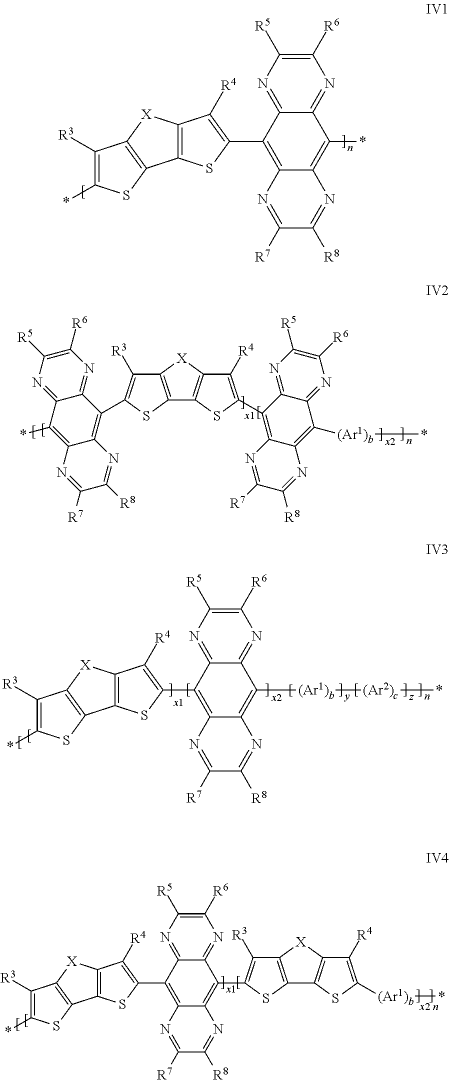

wherein X and R¹⁻⁸ have the meanings of formula I and II or one of the preferred meanings given above and below, Ar¹, Ar², b, c and n have the meanings of formula III,
x1 is >0 and ≦1,
x2 is >0 and ≦1,
y is ≧0 and <1,
z is ≧0 and <1, and
x1+x2+y+z is 1.

In the polymers of subformulae IV1 to IV4, X is preferably Si. Furthermore, in the polymers of subformulae IV1 to IV4, R³ and R⁴ are preferably H, and R¹, R², R⁵, R⁶, R⁷ and R⁸ are preferably selected from the group consisting of straight-chain or branched alkyl, alkoxy or sulfanylalkyl with 1 to 30 C atoms, and straight-chain or branched alkylcarbonyl, alkylcarbonyloxy or alkyloxycarbonyl with 2 to 30 C atoms, each of the aforementioned groups being unsubstituted or substituted by one or more F atoms.

In the polymers of formula IV1, IV2 and IV4, b is preferably 0 or 1, very preferably 0. In the polymers of formula IV3, b+c is preferably 0 or 1, very preferably 0.

In the polymers of formulae IV2 to IV4, x1 is preferably from 0.1 to 0.9, very preferably from 0.3 to 0.7.

In the polymers of formulae IV2 to IV4, x2 is preferably from 0.1 to 0.9, very preferably from 0.3 to 0.7.

In a preferred embodiment, in the polymers of formula IV3 y and z are >0.

In another preferred embodiment, in the polymers of formula IV3 y is >0 and z is 0.

In another preferred embodiment, in the polymers of formula IV3 y=z=0.

If in the polymers of formula IV3 y or z is >0, it is preferably from 0.1 to 0.6, very preferably from 0.1 to 0.3.

In the polymers of the present invention, the total number of repeating units n is preferably from 2 to 10,000. The total number of repeating units n is preferably ≧5, very preferably ≧10, most preferably ≧50, and preferably ≦500, very preferably ≦1,000, most preferably ≦2,000, including any combination of the aforementioned lower and upper limits of n.

The polymers of the present invention include statistical or random copolymers, alternating copolymers and block copolymers, as well as combinations thereof.

Preferred polymers of formula III and IV1 to IV4 are selected of formula V

R^{T1}-chain-R^{T2} V

wherein “chain” denotes a polymer chain of formulae III or IV1 to IV4, and R^{T1} and R^{T2} have independently of each other one of the meanings of R^{S} as defined above, or denote, independently of each other, H, F, Br, Cl, I, —CH₂Cl, —CHO, —CR′═CR″₂, —SiR′R″R′″, —SiR′X′X″, —SiR′R″X′, —SnR′R″R′″, —BR′R″, —B(OR′)(OR″), —B(OH)₂, —O—SO₂—R′, —C≡CH, —C≡C—SiR′₃, —ZnX′ or an endcap group, X′ and X″ denote halogen, R′, R″ and R′″ have independently of each other one of the meanings of R⁰ given above, and two of R′, R″ and R′″ may also form a ring together with the hetero atom to which they are attached.

Preferred endcap groups R^{T1} and R^{T2} are H, C₁₋₂₀ alkyl, or optionally substituted C₆₋₁₂ aryl or C₂₋₁₀ heteroaryl, very preferably H or phenyl.

In the polymers represented by formula III, IV1 to IV4 and V, x1, x2, y and z denote the mole fraction of units D, A, Ar¹ and Ar², respectively, and n denotes the degree of polymerisation or total number of repeating units.

These formulae include block copolymers, random or statistical copolymers and alternating copolymers of D, A, Ar¹ and Ar².

The invention further relates to monomers of formula VI

R^{R1}—(Ar¹)_{b}-(D)_{d}-(Ar²)_{c}-(A)ₐ-(Ar¹)_{b}—R^{R2} VI

wherein D, A, Ar¹, Ar², b, c and d have the meanings of formula III, a is 1, 2 or 3, preferably 1, and R^{R1} and R^{R2} are, preferably independently of each other, selected from the group consisting of Cl, Br, I, O-tosylate, O-triflate, O-mesylate, O-nonaflate, —SiMe₂F, —SiMeF₂, —O—SO₂Z¹, —B(OZ²)₂, —CZ³═C(Z⁴)₂, —C≡CH, —C≡C—Si(Z¹)₃, —ZnX⁰ and —Sn(Z⁴)₃, wherein X⁰ is halogen, preferably Cl, Br or I, Z¹⁻⁴ are selected from the group consisting of alkyl and aryl, preferably C₁-C₁₂-alkyl and C₄-C₁₀-aryl, each being optionally substituted, and two groups Z² may also form a cyclic group together with the B- and O-atoms

Especially preferred are monomers of the following formulae

R^{R1}—Ar¹-D-Ar²-A-R^{R2} VI1

R^{R1}-D-A-R^{R2} VI2

R^{R1}-A-R^{R2} VI3

R^{R1}—Ar¹-A-R^{R2} VI4

R^{R1}—Ar¹-A-Ar²—R^{R2} VI5

wherein D, A, Ar¹, Ar², R^{R1} and R^{R2} are as defined in formula VI.

Especially preferred are repeating units, monomers and polymers of formulae I, II, III, IV1-IV4, V, VI, VI1-V15 and their subformulae wherein Ar¹ and/or Ar² denote arylene or heteroarylene, preferably having electron donor properties, selected from the group consisting of the following formulae

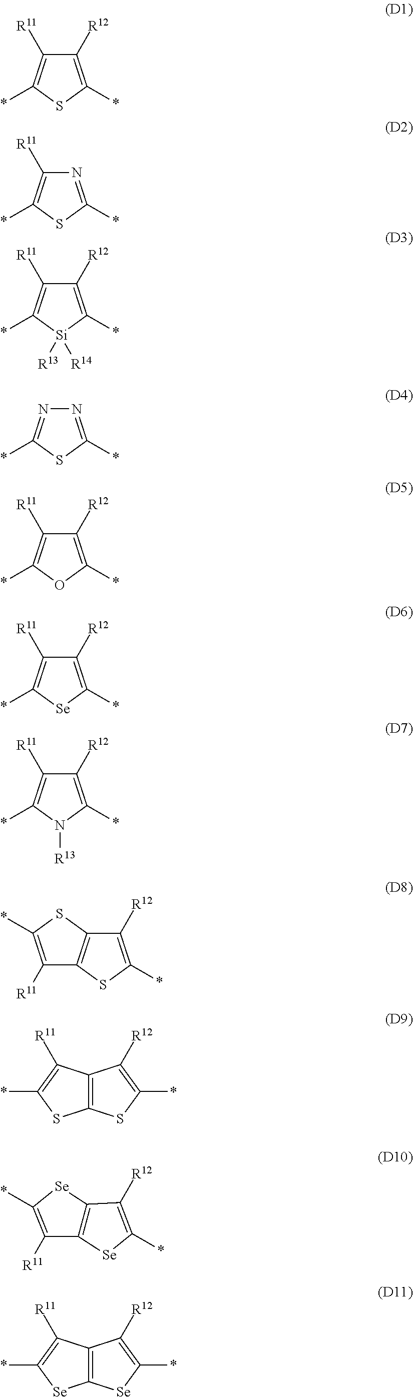

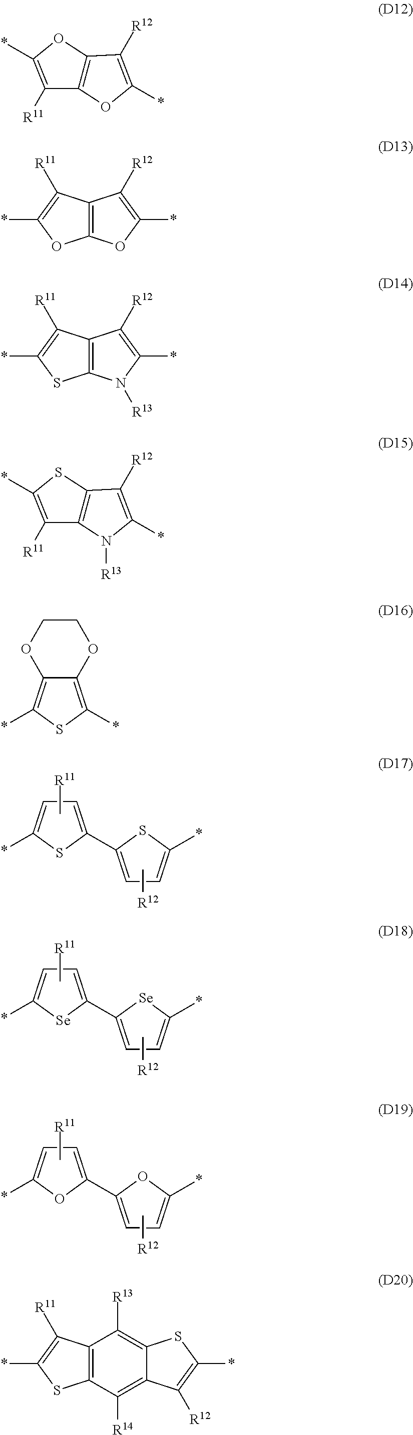

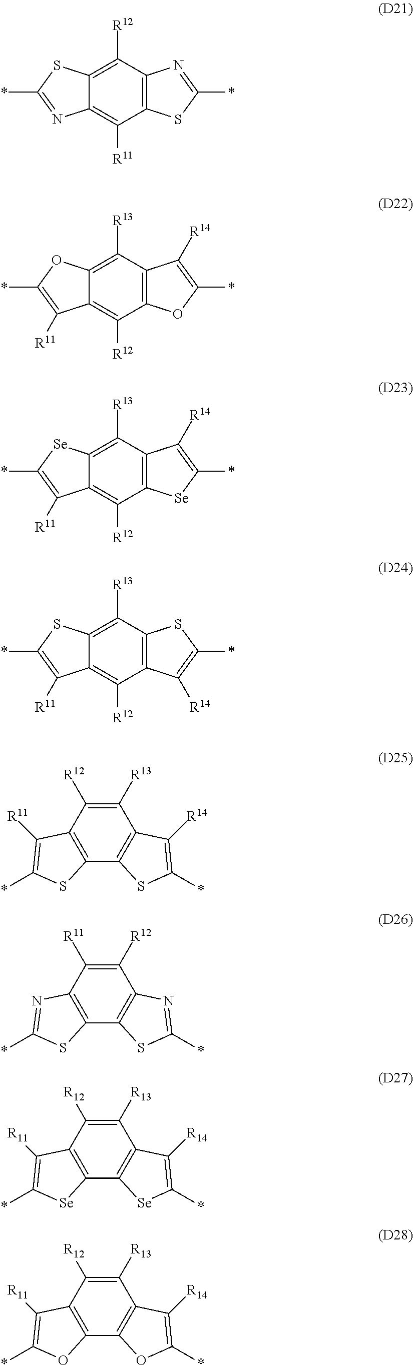

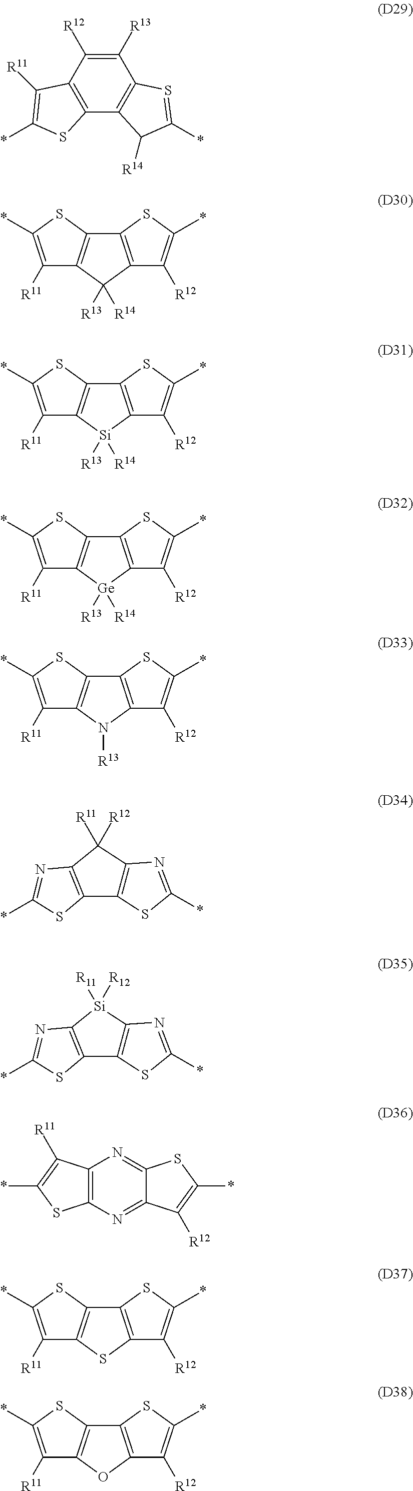

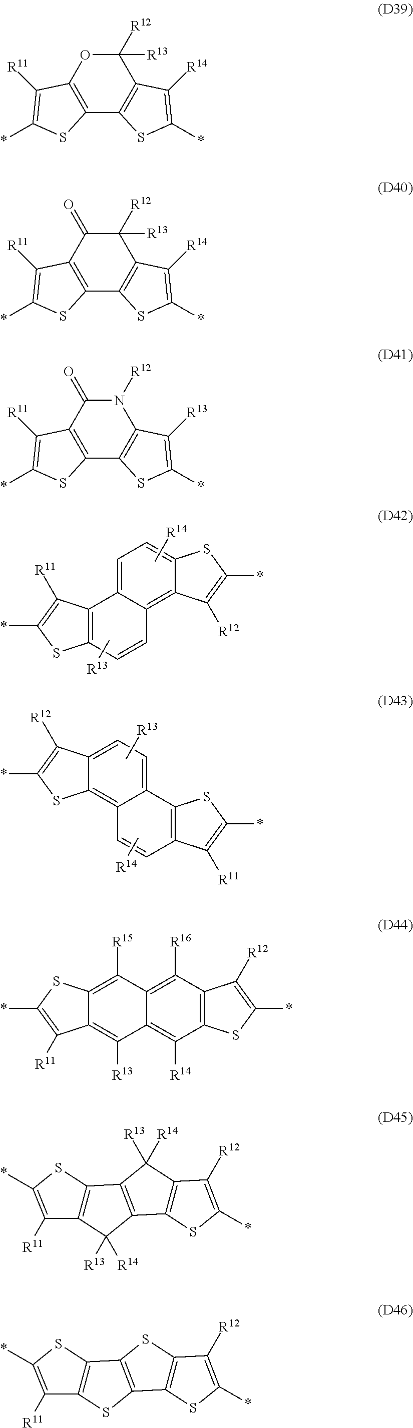

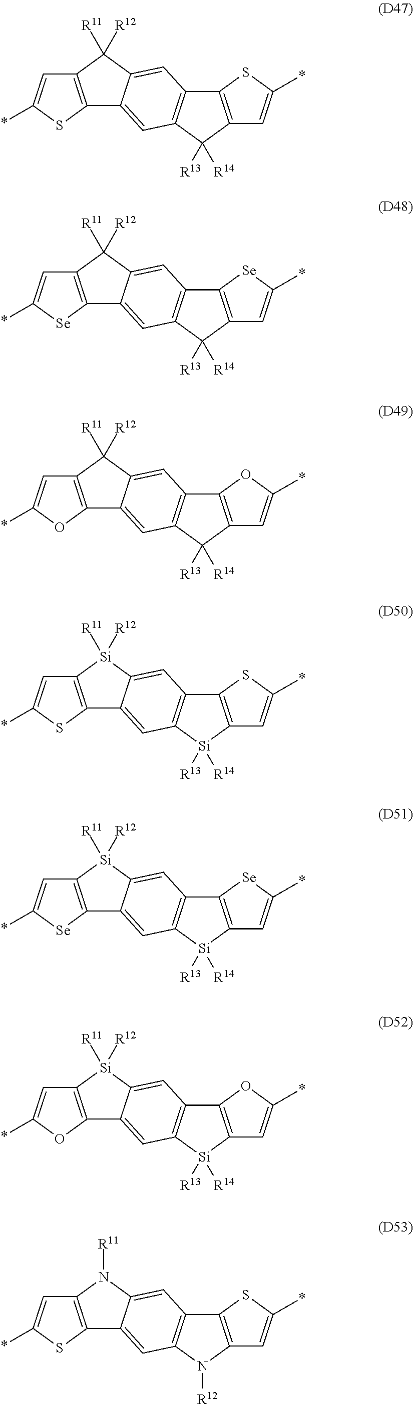

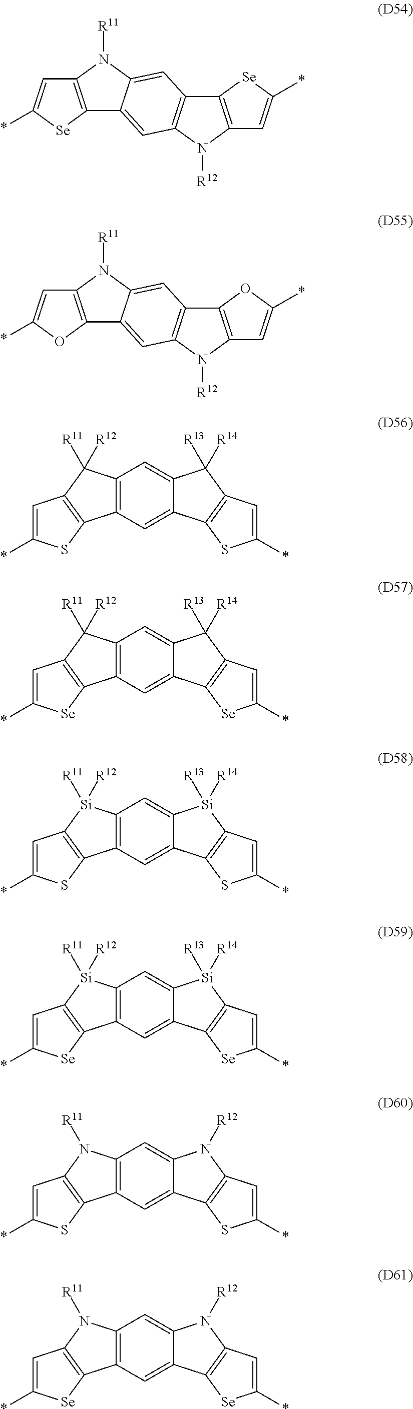

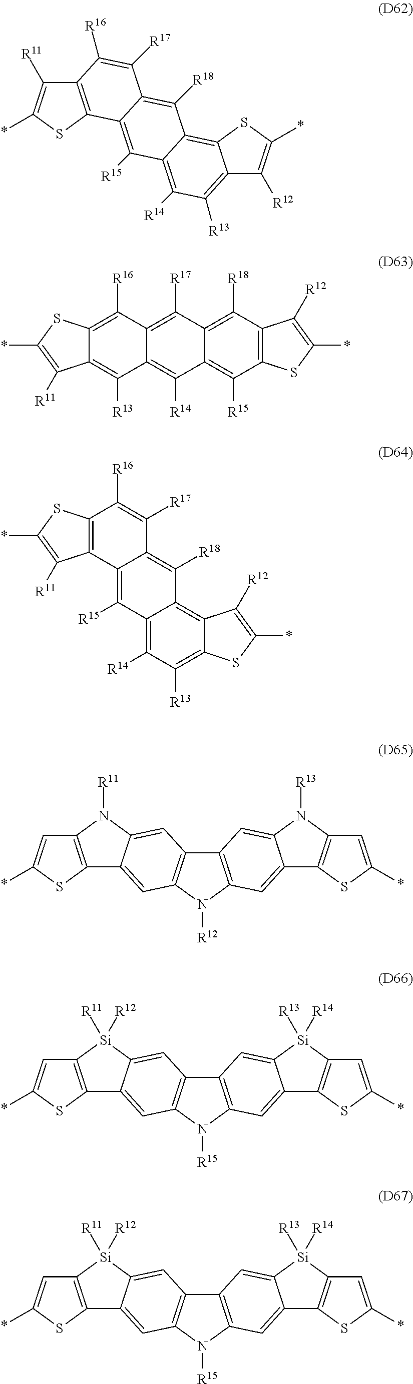

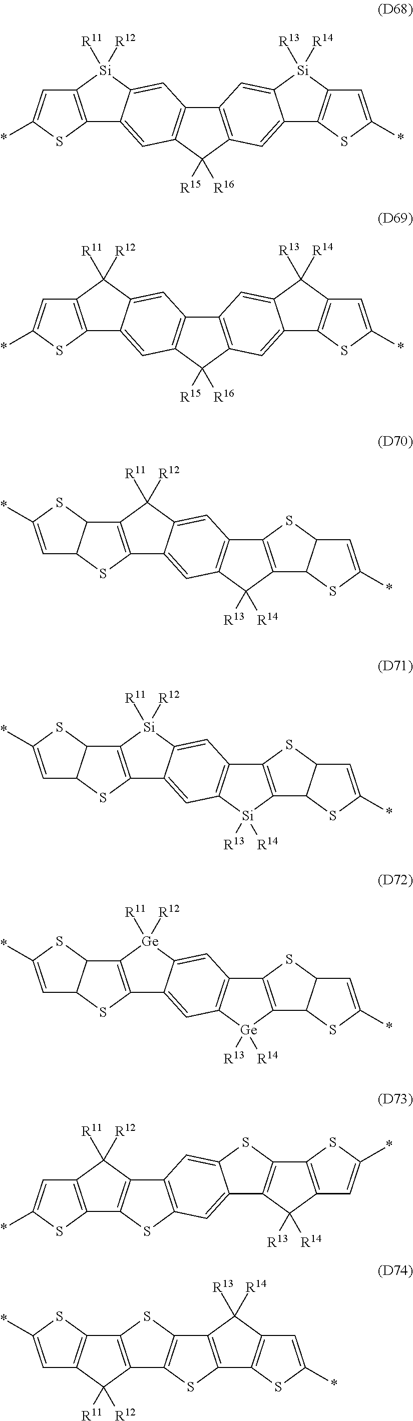

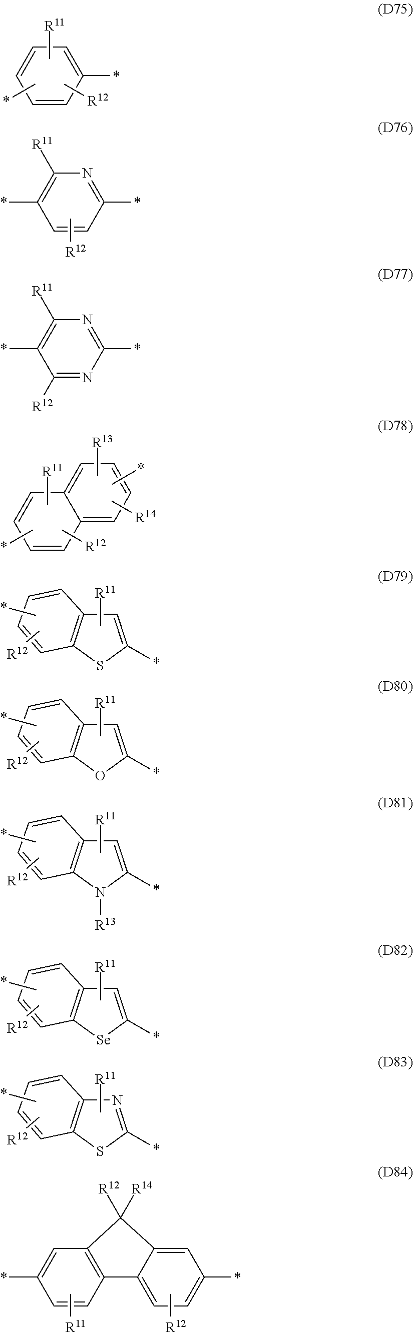

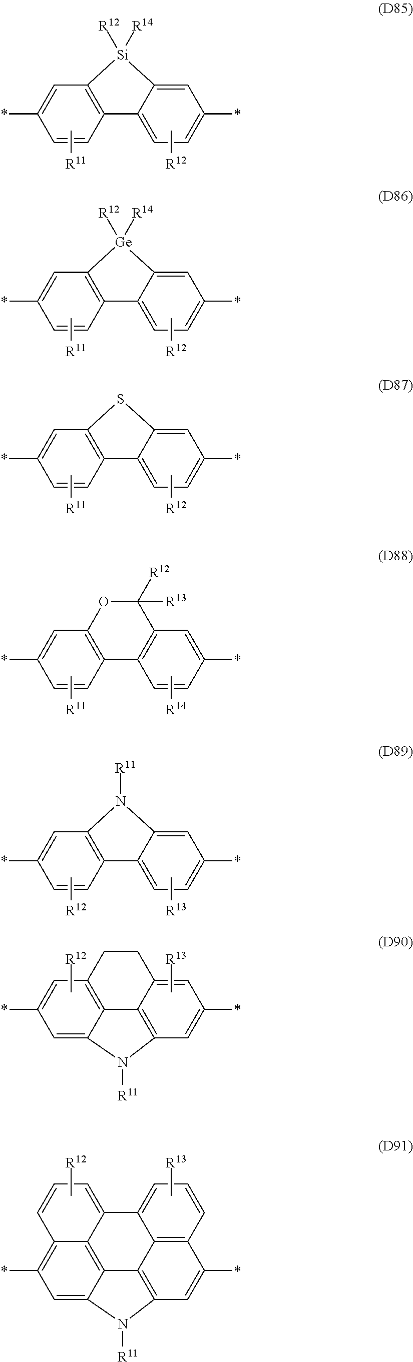

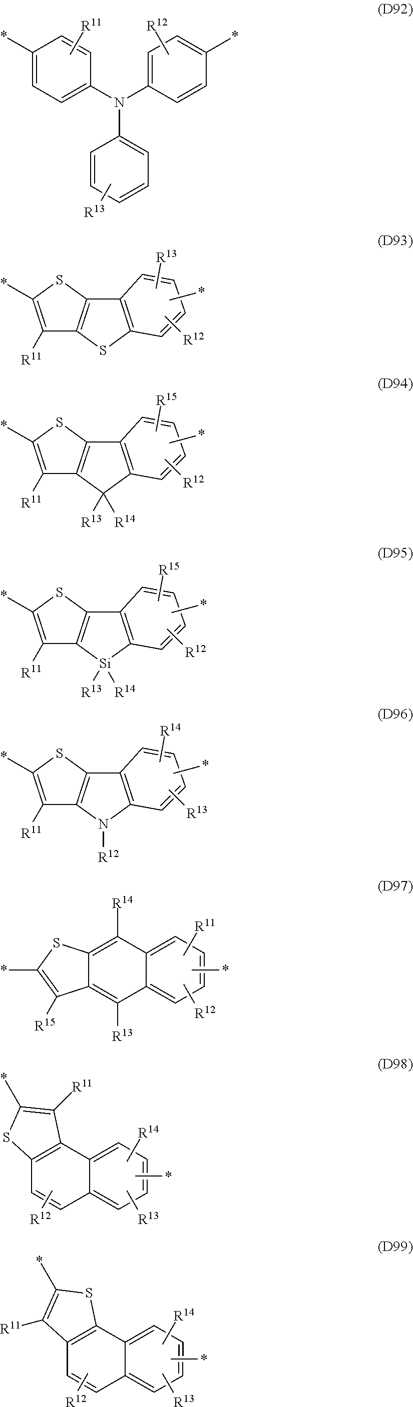

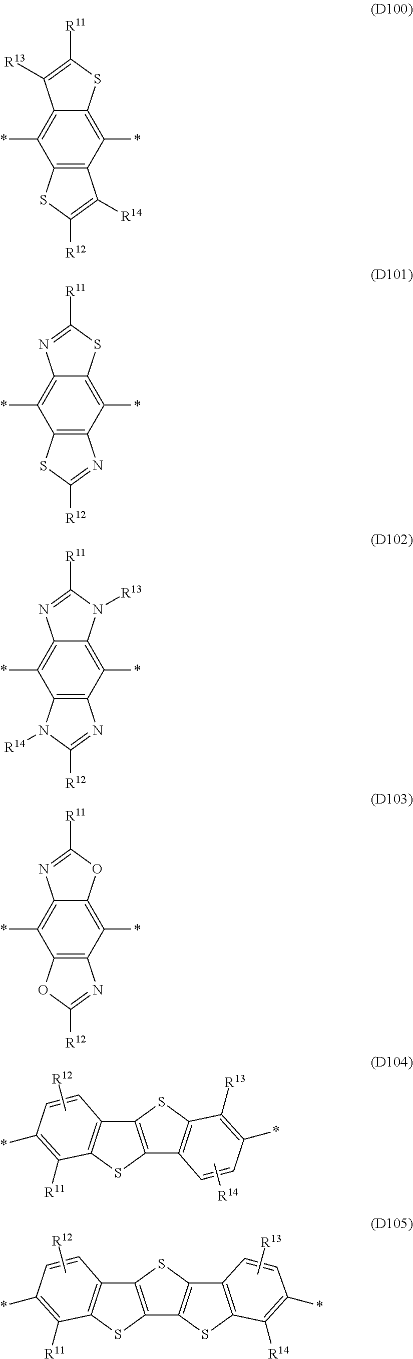

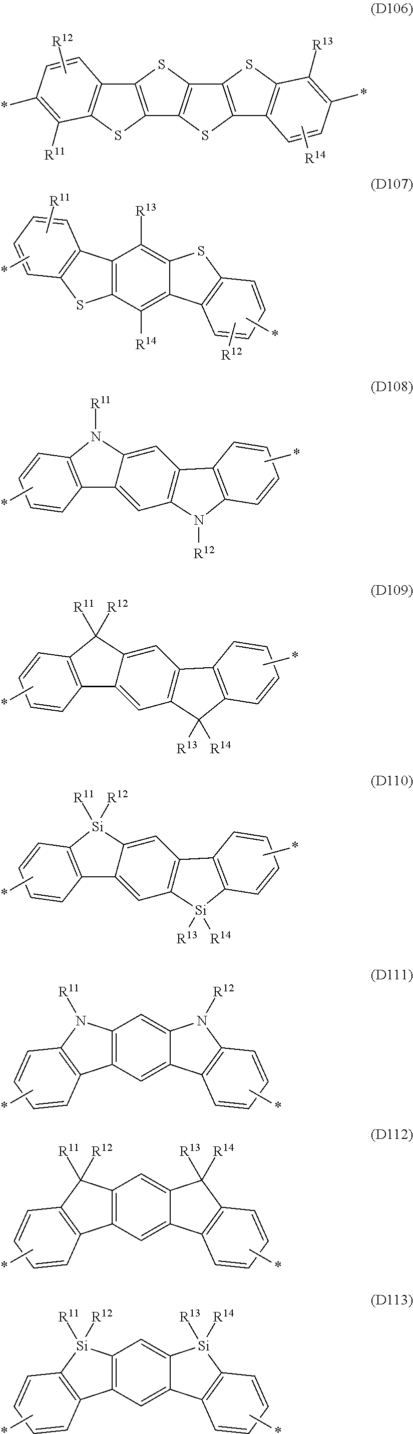

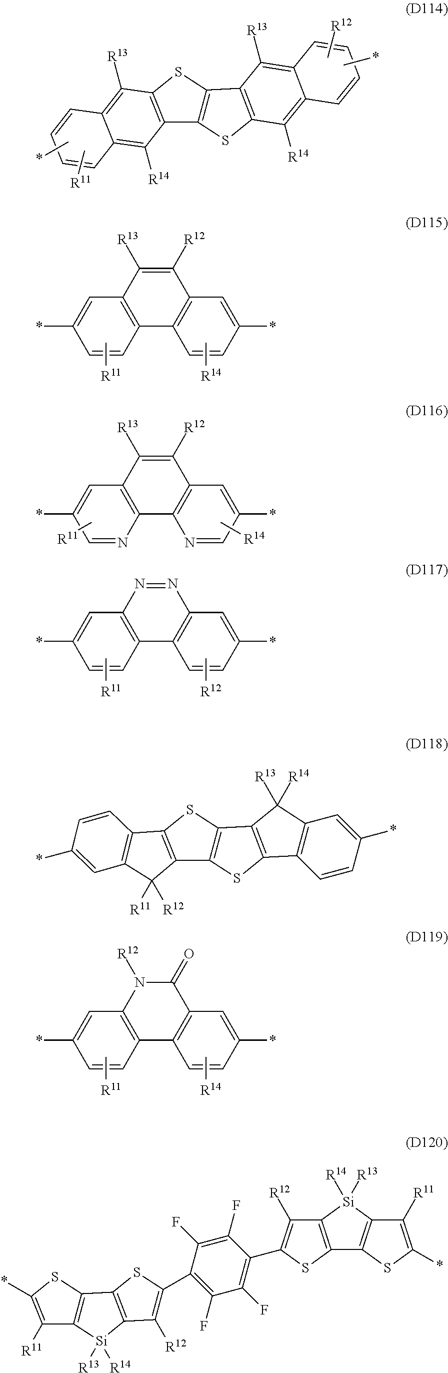

wherein R¹¹, R¹², R¹³, R¹⁴, R¹⁵, R¹⁶, R¹⁷ and R¹⁸ independently of each other denote H or have one of the meanings of R^{S} as defined above and below.

Further preferred are repeating units, monomers and polymers of formulae I, II, III, IV1-IV4, V, VI and their subformulae wherein Ar¹ and/or Ar² denotes arylene or heteroarylene, preferably having electron acceptor properties, selected from the group consisting of the following formulae

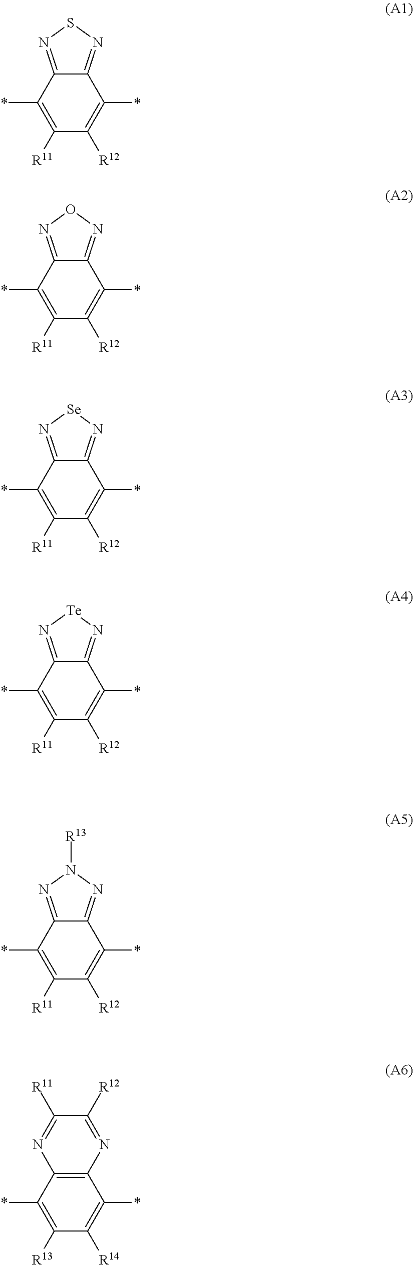

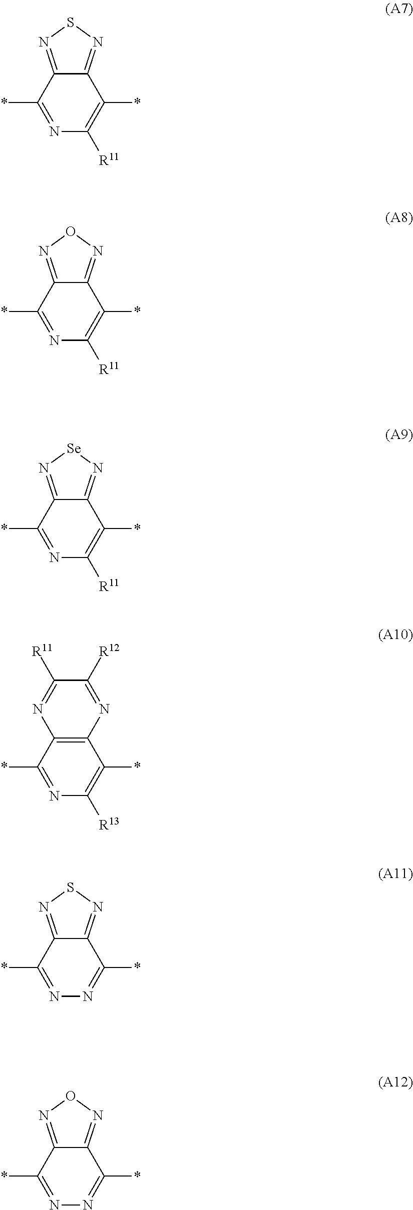

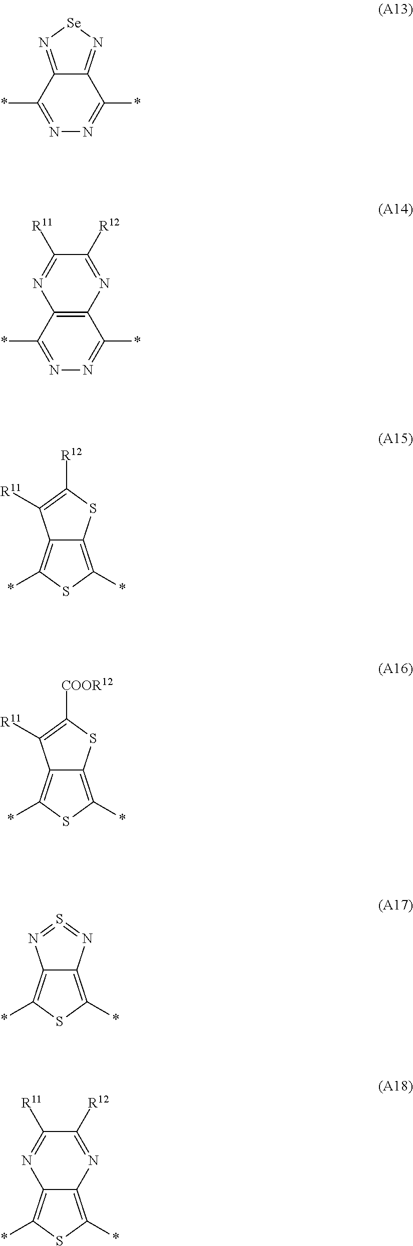

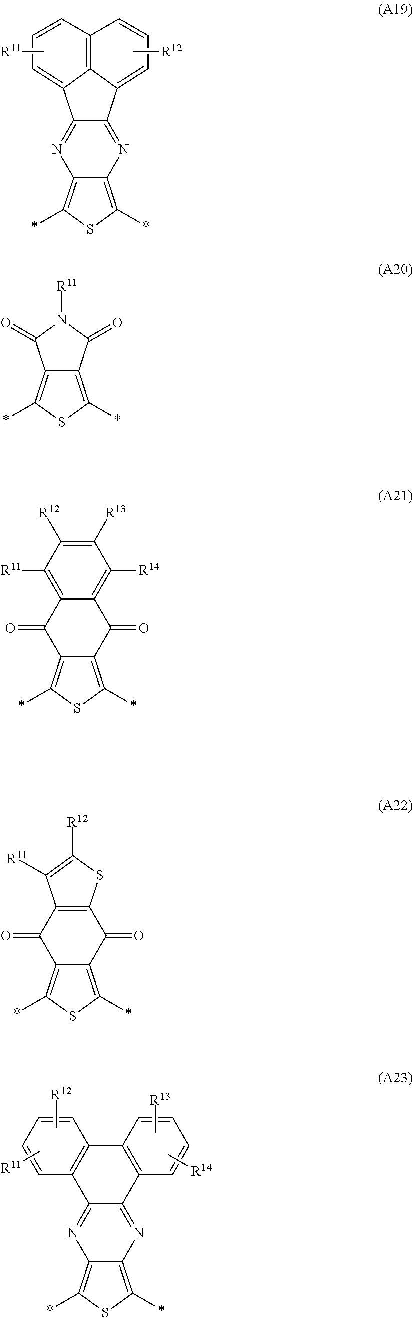

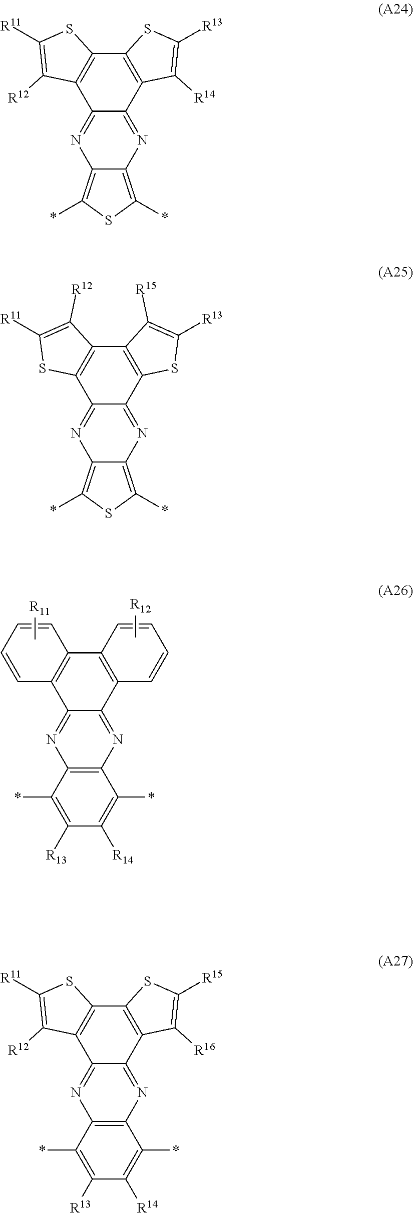

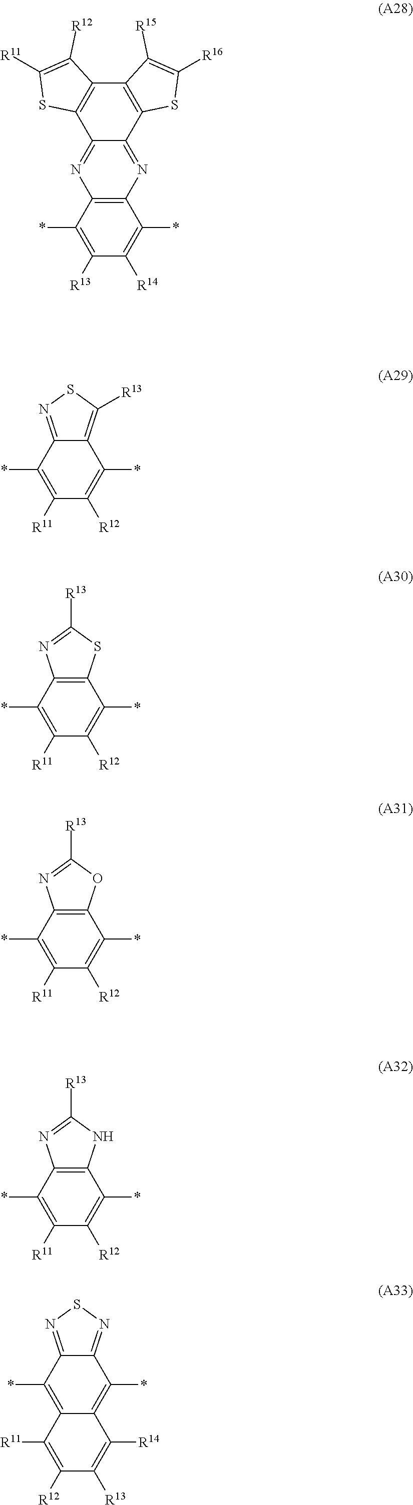

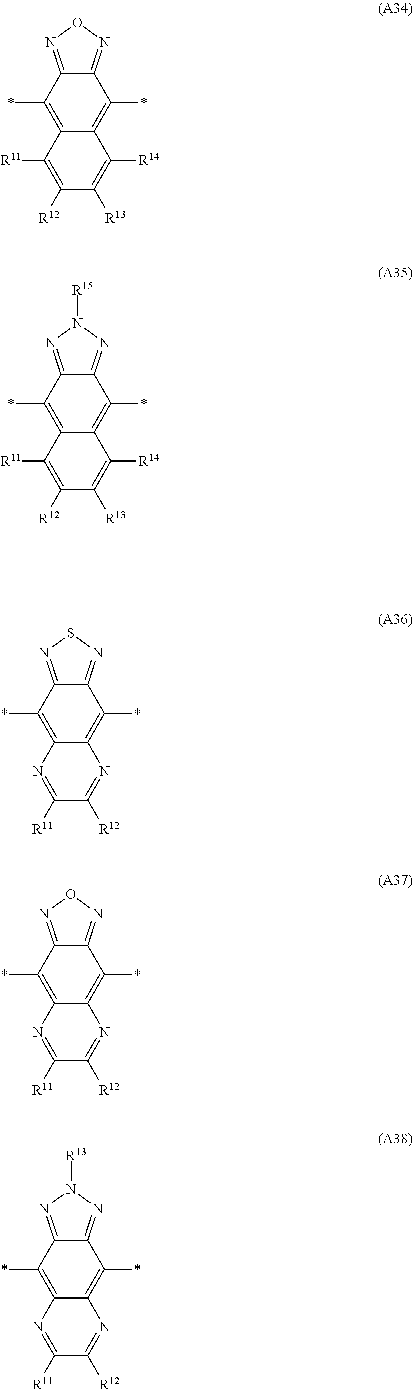

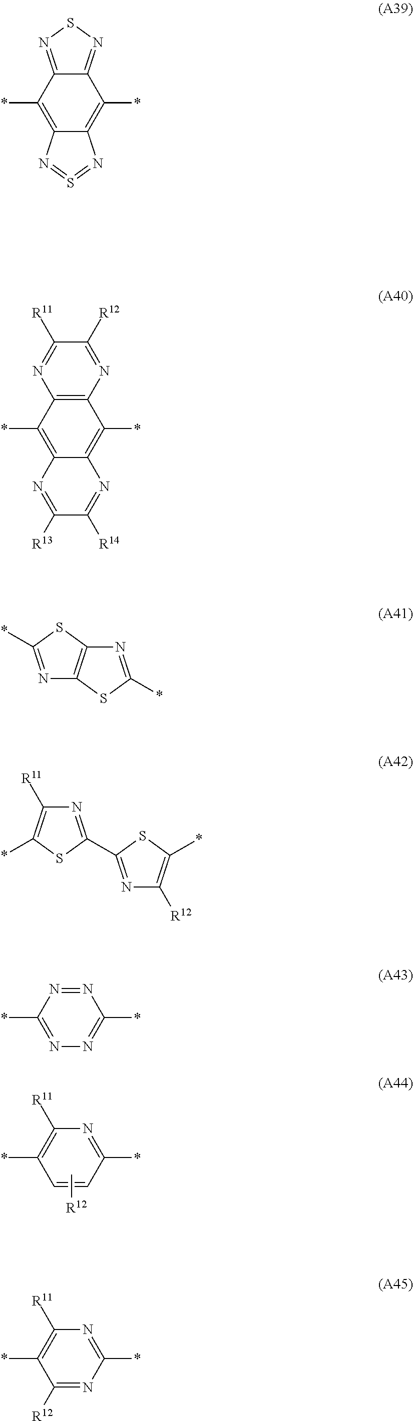

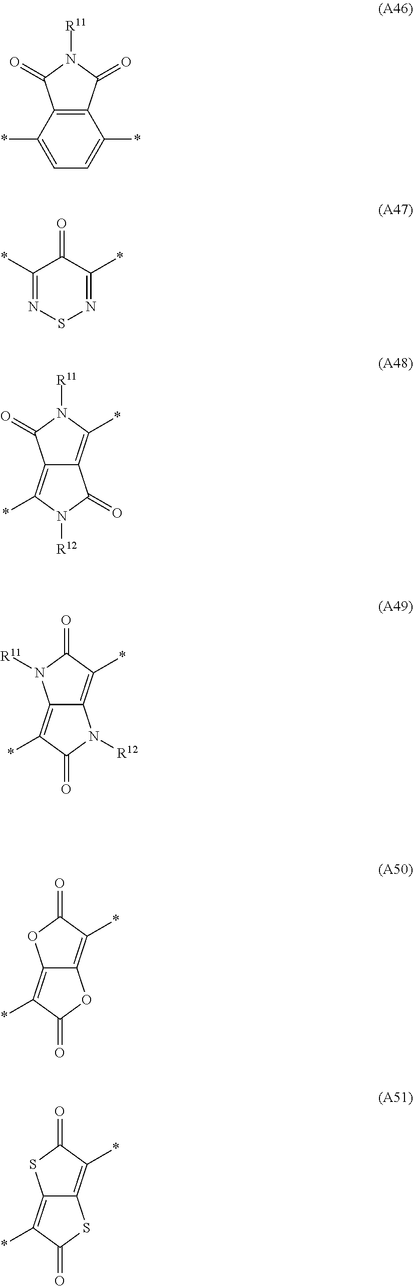

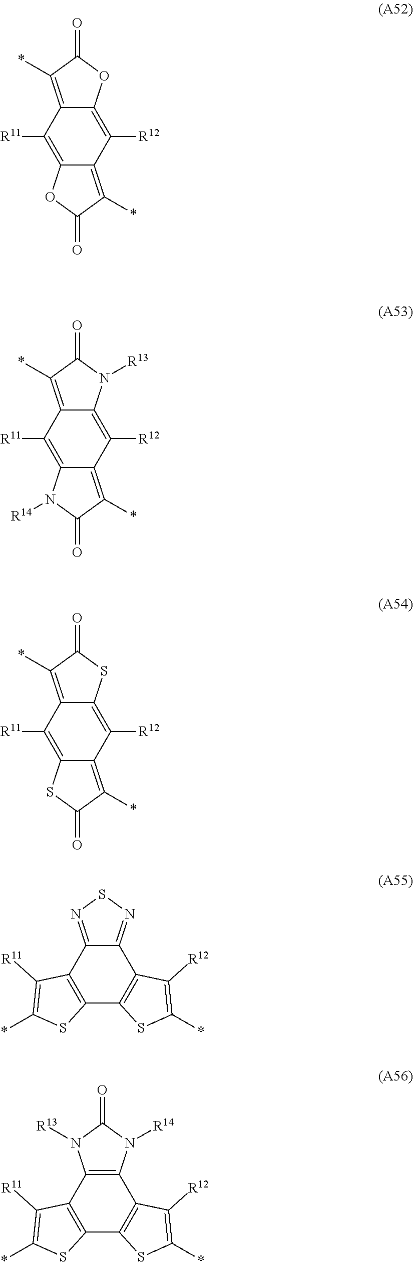

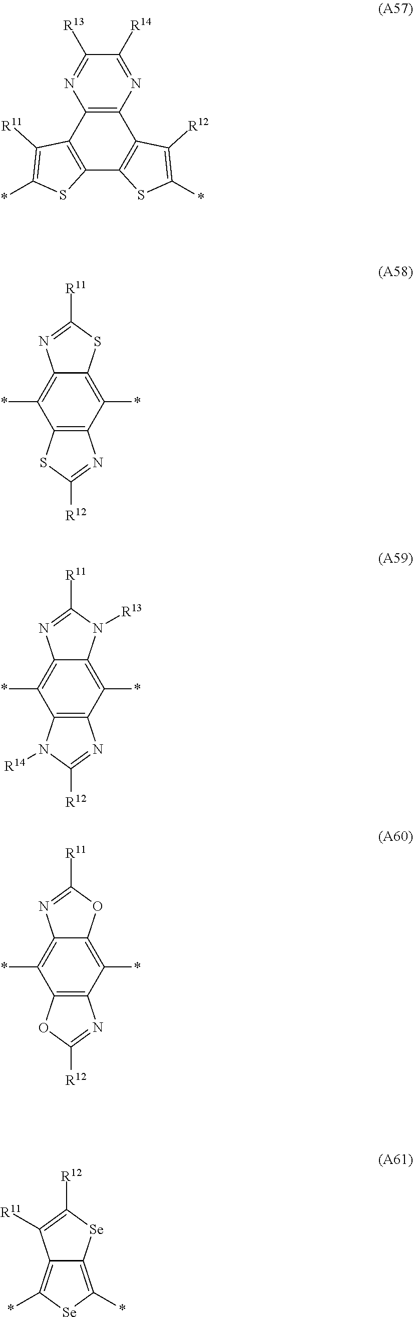

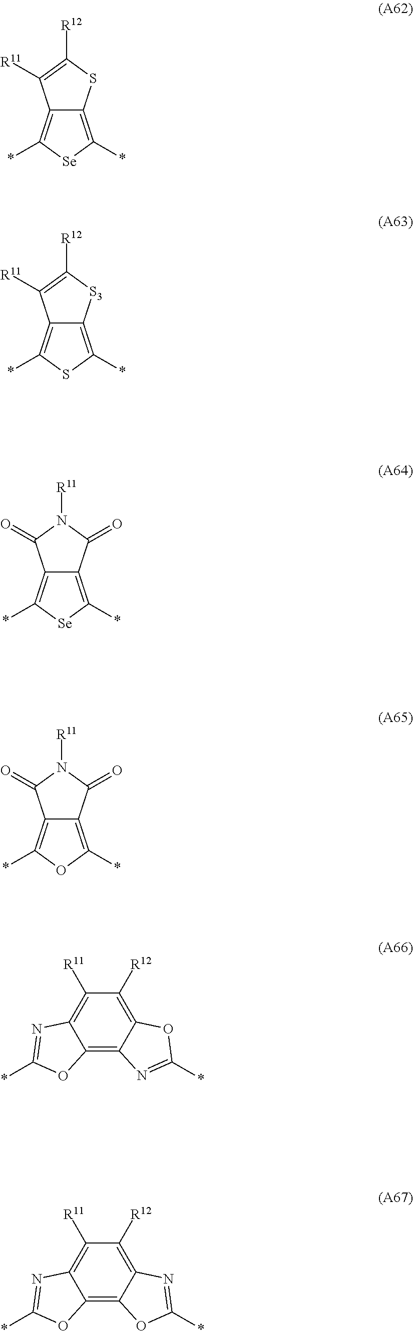

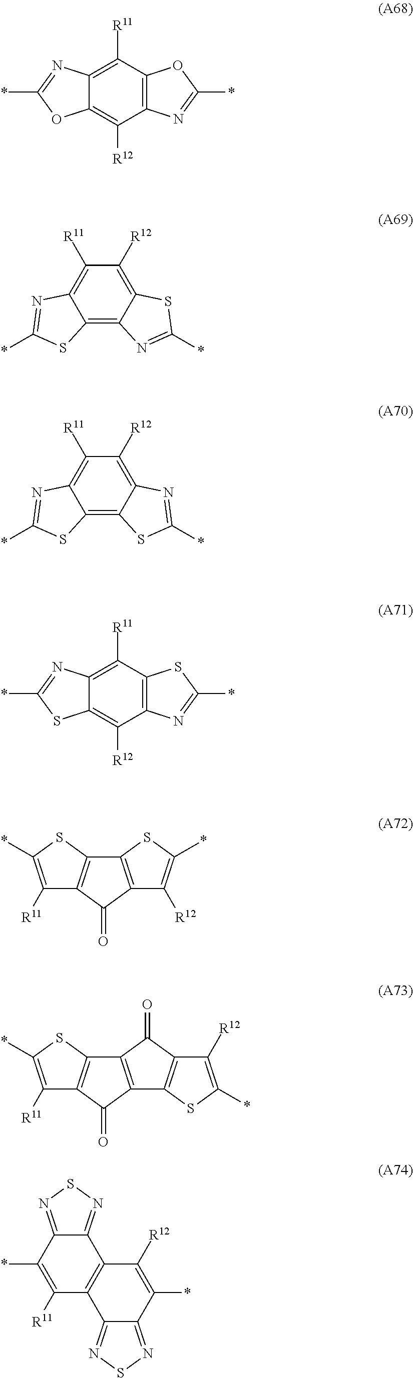

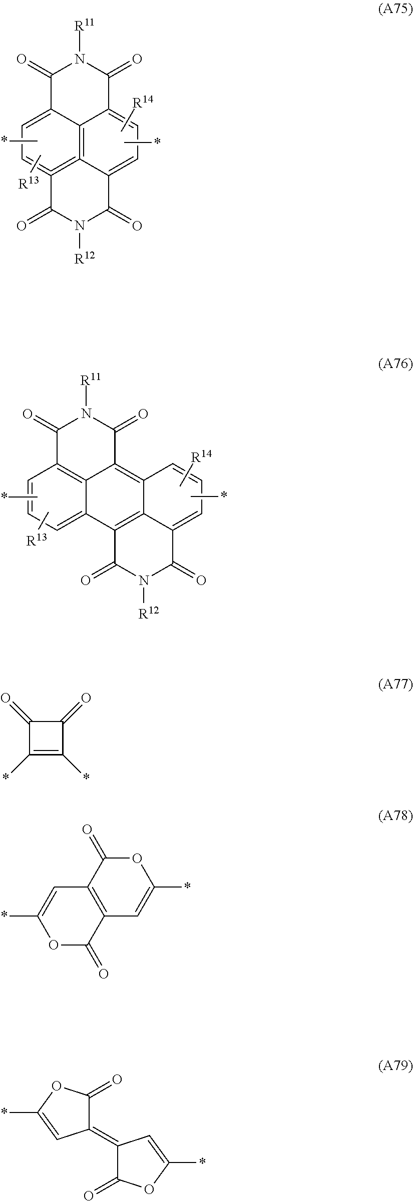

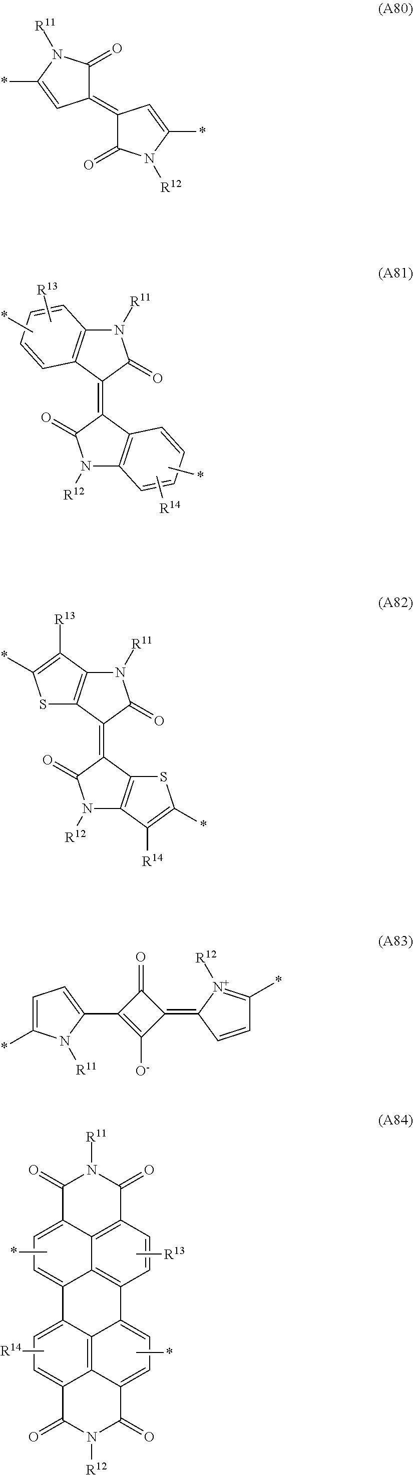

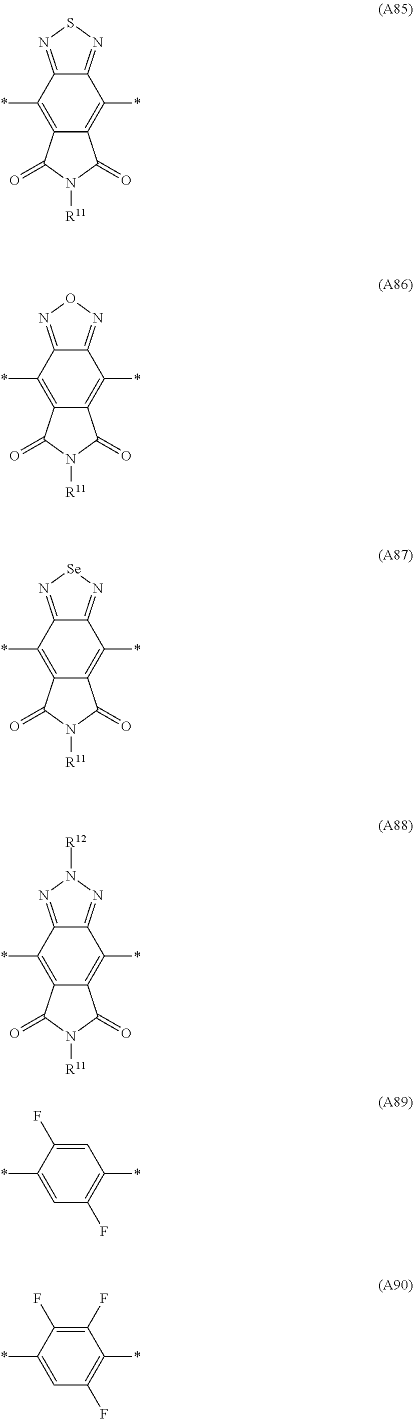

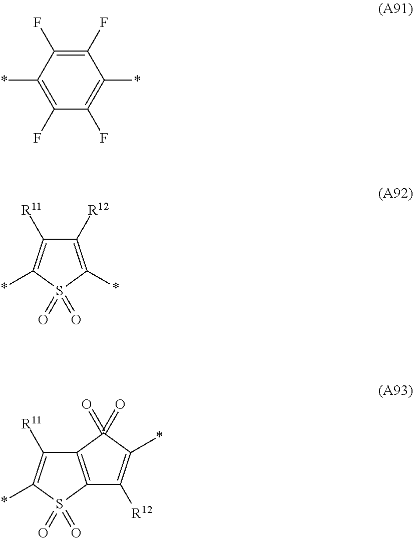

wherein R¹¹, R¹², R¹³, R¹⁴, R¹⁵ and R¹⁶ independently of each other denote H or have one of the meanings of R^{S} as defined above and below.

Further preferred are repeating units, monomers and polymers of formulae I-VI and their subformulae selected from the following list of preferred embodiments:
y is >0 and <1 and z is 0,
y is >0 and <1 and z is >0 and <1,
n is at least 5, preferably at least 10, very preferably at least 50, and up to 2,000, preferably up to 500.
M_{w} is at least 5,000, preferably at least 8,000, very preferably at least 10,000, and preferably up to 300,000, very preferably up to 100,000,
all groups R^{S} denote H,
at least one group R^{S} is different from H,
R^{S} is selected, on each occurrence identically or differently, from the group consisting of primary alkyl with 1 to 30 C atoms, secondary alkyl with 3 to 30 C atoms, and tertiary alkyl with 4 to 30 C atoms, wherein in all these groups one or more H atoms are optionally replaced by F,
R^{S} is selected, on each occurrence identically or differently, from the group consisting of primary alkoxy or sulfanylalkyl with 1 to 30 C atoms, secondary alkoxy or sulfanylalkyl with 3 to 30 C atoms, and tertiary alkoxy or sulfanylalkyl with 4 to 30 C atoms, wherein in all these groups one or more H atoms are optionally replaced by F,
R^{S} is selected, on each occurrence identically or differently, from the group consisting of alkylcarbonyl, alkoxycarbonyl and alkylcarbonyloxy, all of which are straight-chain or branched, are optionally fluorinated, and have from 2 to 30 C atoms,
R^{S} denotes, on each occurrence identically or differently, F, Cl, Br, I, CN, R⁹, —C(O)—R⁹, —C(O)—O—R⁹, or —O—C(O)—R⁹, —SO₂—R⁹, —SO₃—R⁹, wherein R⁹ is straight-chain, branched or cyclic alkyl with 1 to 30 C atoms, in which one or more non-adjacent C atoms are optionally replaced by —O—, —S—, —C(O)—, —C(O)—O—, —O—C(O)—, —O—C(O)—O—, —SO₂—, —SO₃—, —CR⁰═CR⁰⁰— or —C≡C— and in which one or more H atoms are optionally replaced by F, Cl, Br, I or CN, or R⁹ is aryl or heteroaryl having 4 to 30 ring atoms which is unsubstituted or which is substituted by one or more halogen atoms or by one or more groups R¹ as defined above,
R^{S} is selected, on each occurrence identically or differently, from the group consisting of aryl and heteroaryl, each of which is optionally fluorinated, alkylated or alkoxylated and has 4 to 30 ring atoms,
R^{S} is selected, on each occurrence identically or differently, from the group consisting of aryloxy and heteroaryloxy, each of which is optionally alkylated or alkoxylated and has 4 to 30 ring atoms,
R⁰ and R⁰⁰ are selected from H or C₁-C₁₀-alkyl,
R⁵ and R⁶ are independently of each other selected from H, halogen, —CH₂Cl, —CHO, —CH═CH₂, —SiR′R″R′″, —SnR′R″R′″, —BR′R″, —B(OR′)(OR″), —B(OH)₂, P-Sp, C₁-C₂₀-alkyl, C₁-C₂₀-alkoxy, C₂-C₂₀-alkenyl, C₁-C₂₀-fluoroalkyl and optionally substituted aryl or heteroaryl, preferably phenyl,
R^{R1} and R^{R2} are independently of each other selected from the group consisting of Cl, Br, I, O-tosylate, O-triflate, O-mesylate, O-nonaflate, —SiMe₂F, —SiMeF₂, —O—SO₂Z¹, —B(OZ²)₂, —CZ³═C(Z⁴)₂, —C≡CH, —C≡C—Si(Z¹)₃, —ZnX⁰ and —Sn(Z⁴)₃, wherein X⁰ is halogen, preferably Cl, Br or I, Z¹⁻⁴ are selected from the group consisting of alkyl and aryl, preferably C₁-C₁₂-alkyl and C₄-C₁₀-aryl, each being optionally substituted, and two groups Z² may also form a cyclic group together with the B- and O-atoms.

The polymers and monomers of the present invention can be synthesized according to or in analogy to methods that are known to the skilled person and are described in the literature. Other methods of preparation can be taken from the examples. For example, the polymers can be suitably prepared by aryl-aryl coupling reactions, such as Yamamoto coupling, Suzuki coupling, Stille coupling, Sonogashira coupling, Heck coupling or Buchwald coupling. Suzuki coupling, Stille coupling, C—H activation coupling and Yamamoto coupling are especially preferred. The monomers which are polymerised to form the repeat units of the polymers can be prepared according to methods which are known to the person skilled in the art.

Preferably the polymers are prepared from monomers of formula VI or their subformulae as described above and below.

Another aspect of the invention is a process for preparing a polymer by coupling one or more identical or different monomeric units of formula I1 and I2, or one or more monomers selected from formulae VI or VI1 to VI5 with each other and/or with one or more co-monomers in a polymerisation reaction, preferably in an aryl-aryl coupling reaction.

Suitable and preferred monomers and co-monomers are selected from the following formulae

R^{R1}—Ar¹-D-Ar²-A-R^{R2} VI1

R^{R1}-D-A-R^{R2} VI2

R^{R1}-A-R^{R2} VI3

R^{R1}—Ar¹-A-R^{R2} VI4

R^{R1}—Ar¹-A-Ar²—R^{R2} VI5

R^{R1}-D-R^{R2} VII

R^{R1}—Ar¹—R^{R2} VIII

R^{R1}—Ar²—R^{R2} IX

wherein D, A, Ar¹ and Ar² are as defined in formula III and R^{R1} and R^{R2} are as defined in formula VI.

Very preferred is a process for preparing a polymer by coupling one or more monomers selected from formula VI, V1 to VI5 and VII to IX in an aryl-aryl coupling reaction, wherein preferably R^{R1} and R^{R2} are selected from H, Cl, Br, I, —B(OZ²)₂ and —Sn(Z⁴)₃.

Preferred aryl-aryl coupling and polymerisation methods used in the processes described above and below are Yamamoto coupling, Kumada coupling, Negishi coupling, Suzuki coupling, Stille coupling, Sonogashira coupling, Heck coupling, C—H activation coupling, Ullmann coupling or Buchwald coupling. Especially preferred are Suzuki coupling, Negishi coupling, Stille coupling and Yamamoto coupling. Suzuki coupling is described for example in WO 00/53656 A1. Negishi coupling is described for example in J. Chem. Soc., Chem. Commun., 1977, 683-684. Yamamoto coupling is described in for, and example in T. Yamamoto et al., Prog. Polym. Sci., 1993, 17, 1153-1205, or WO 2004/022626 A1. Stille coupling is described for example in Z. Bao et al., J. Am. Chem. Soc., 1995, 117, 12426-12435. C—H activation is described for example in M. Leclerc et al, Angew. Chem. Int. Ed., 2012, 51, 2068-2071. For example, when using Yamamoto coupling, monomers having two reactive halide groups are preferably used. When using Suzuki coupling, compounds of formula II having two reactive boronic acid or boronic acid ester groups or two reactive halide groups are preferably used. When using Stille coupling, monomers having two reactive stannane groups or two reactive halide groups are preferably used. When using Negishi coupling, monomers having two reactive organozinc groups or two reactive halide groups are preferably used. When synthesizing a linear polymer by C—H activation polymerisation, preferably a monomer as described above is used wherein at least one reactive group is an activated hydrogen bond.

Preferred catalysts, especially for Suzuki, Negishi or Stille coupling, are selected from Pd(0) complexes or Pd(II) salts. Preferred Pd(0) complexes are those bearing at least one phosphine ligand such as Pd(Ph₃P)₄. Another preferred phosphine ligand is tris(ortho-tolyl)phosphine, i.e. Pd(o-Tol₃P)₄. Preferred Pd(II) salts include palladium acetate, i.e. Pd(OAc)₂. Alternatively the Pd(0) complex can be prepared by mixing a Pd(0) dibenzylideneacetone complex, for example tris(dibenzyl-ideneacetone)dipalladium(0), bis(dibenzylideneacetone)palladium(0), or Pd(II) salts e.g. palladium acetate, with a phosphine ligand, for example triphenylphosphine, tris(ortho-tolyl)phosphine or tri(tert-butyl)phosphine. Suzuki polymerisation is performed in the presence of a base, for example sodium carbonate, potassium carbonate, cesium carbonate, lithium hydroxide, potassium phosphate or an organic base such as tetraethylammonium carbonate or tetraethylammonium hydroxide. Yamamoto polymerisation employs a Ni(0) complex, for example bis(1,5-cyclooctadienyl) nickel(0).

Suzuki, Stille or C—H activation coupling polymerisation may be used to prepare homopolymers as well as statistical, alternating and block random copolymers. Statistical or block copolymers can be prepared for example from the above monomers of formula VI or its subformulae, wherein one of the reactive groups is halogen and the other reactive group is a C—H activated bond, a boronic acid or boronic acid derivative group, or an alkylstannane. The synthesis of statistical, alternating and block copolymers is described in detail for example in WO 03/048225 A2 or WO 2005/014688 A2.

As an alternative to halogen groups as described above, leaving groups of formula —O—SO₂Z¹ can be used, wherein Z¹ is as described above. Particular preferred examples of such leaving groups are tosylate, mesylate and triflate.

The synthesis of the 7,7-bis-(2-alkyl)-3,4-dithia-7-sila-cyclopenta[a]pentalene monomer has been previously described, for example in J. Hou et al., J. Am. Chem. Soc., 2008, 130, 16144-16145.

The synthesis of the 2,3,7,8-tetraalkyl-pyrazino[2,3-g]quinoxaline monomer is exemplarily shown in Scheme 1 and Scheme 2.

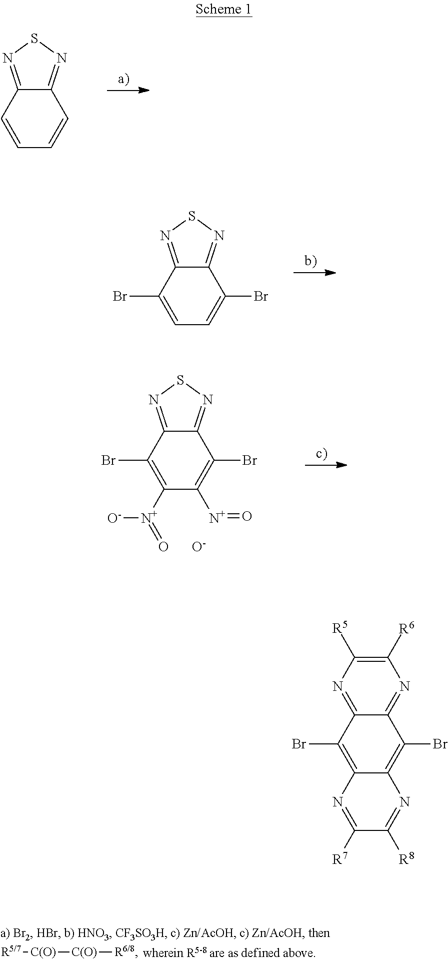

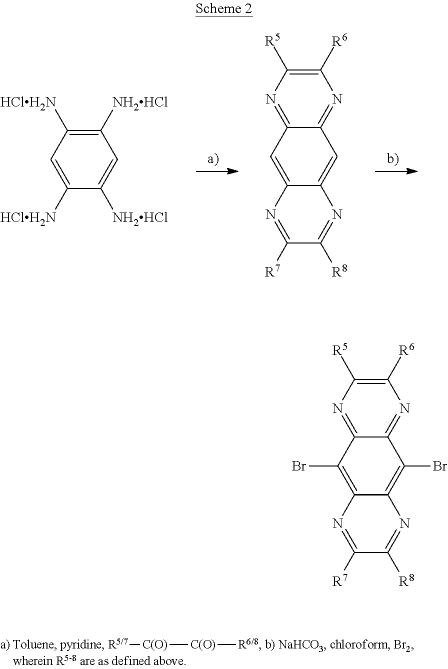

The synthesis of alternating, random and statistical block co-polymers is exemplarily shown in Scheme 3.

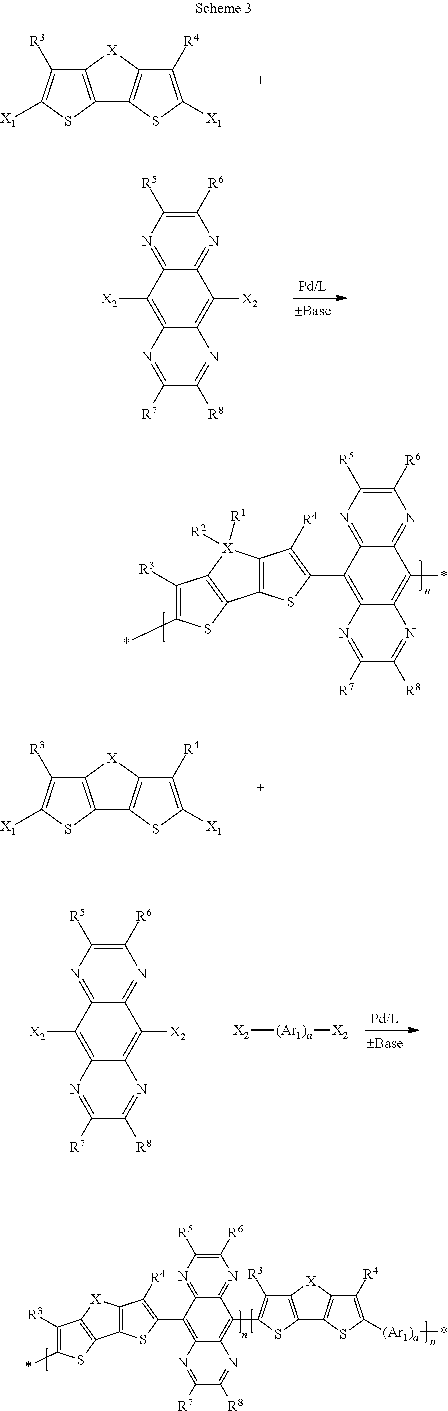

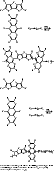

The methods of preparing polymers as described above and below are another aspect of the invention.

The compounds and polymers according to the present invention can also be used in mixtures or polymer blends, for example together with monomeric compounds or together with other polymers having charge-transport, semiconducting, electrically conducting, photoconducting and/or light emitting semiconducting properties, or for example with polymers having hole blocking or electron blocking properties for use as interlayers or charge blocking layers in OLED devices. Thus, another aspect of the invention relates to a polymer blend comprising one or more polymers according to the present invention and one or more further polymers having one or more of the above-mentioned properties. These blends can be prepared by conventional methods that are described in prior art and known to the skilled person. Typically the polymers are mixed with each other or dissolved in suitable solvents and the solutions combined.

Another aspect of the invention relates to a formulation comprising one or more small molecules, polymers, mixtures or polymer blends as described above and below and one or more organic solvents.

Preferred solvents are aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetramethyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers. Solvents with relatively low polarity are generally preferred. For inkjet printing solvents and solvent mixtures with high boiling temperatures are preferred. For spin coating alkylated benzenes like xylene and toluene are preferred.

Examples of especially preferred solvents include, without limitation, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, N,N-dimethylformamide, dimethylacetamide, dimethylsulfoxide, tetraline, decaline, indane, methyl benzoate, ethyl benzoate, mesitylene and/or mixtures thereof.

The concentration of the compounds or polymers in the solution is preferably 0.1 to 10% by weight, more preferably 0.5 to 5% by weight. Optionally, the solution also comprises one or more binders to adjust the rheological properties, as described for example in WO 2005/055248 A1.

After the appropriate mixing and ageing, solutions are evaluated as one of the following categories: complete solution, borderline solution or insoluble. The contour line is drawn to outline the solubility parameter-hydrogen bonding limits dividing solubility and insolubility. ‘Complete’ solvents falling within the solubility area can be chosen from literature values such as published in “Crowley, J. D., Teague, G. S. Jr and Lowe, J. W. Jr., Journal of Paint Technology, 1966, 38 (496), 296”. Solvent blends may also be used and can be identified as described in “Solvents, W. H. Ellis, Federation of Societies for Coatings Technology, p 9-10, 1986”. Such a procedure may lead to a blend of ‘non’ solvents that will dissolve both the polymers of the present invention, although it is desirable to have at least one true solvent in a blend.

The compounds and polymers according to the present invention can also be used in patterned OSC layers in the devices as described above and below. For applications in modern microelectronics it is generally desirable to generate small structures or patterns to reduce cost (more devices/unit area), and power consumption. Patterning of thin layers comprising a polymer according to the present invention can be carried out for example by photolithography, electron beam lithography or laser patterning.

For use as thin layers in electronic or electrooptical devices the compounds, polymers, polymer blends or formulations of the present invention may be deposited by any suitable method. Liquid coating of devices is more desirable than vacuum deposition techniques. Solution deposition methods are especially preferred. The formulations of the present invention enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing.

Ink jet printing is particularly preferred when high resolution layers and devices needs to be prepared. Selected formulations of the present invention may be applied to prefabricated device substrates by ink jet printing or microdispensing. Preferably industrial piezoelectric print heads such as but not limited to those supplied by Aprion, Hitachi-Koki, InkJet Technology, On Target Technology, Picojet, Spectra, Trident, Xaar may be used to apply the organic semiconductor layer to a substrate. Additionally semi-industrial heads such as those manufactured by Brother, Epson, Konica, Seiko Instruments Toshiba TEC or single nozzle microdispensers such as those produced by Microdrop and Microfab may be used.

In order to be applied by ink jet printing or microdispensing, the compounds or polymers should be first dissolved in a suitable solvent. Solvents must fulfil the requirements stated above and must not have any detrimental effect on the chosen print head. Additionally, solvents should have boiling points >100° C., preferably >140° C. and more preferably >150° C. in order to prevent operability problems caused by the solution drying out inside the print head. Apart from the solvents mentioned above, suitable solvents include substituted and non-substituted xylene derivatives, di-C₁₋₂-alkyl formamide, substituted and non-substituted anisoles and other phenol-ether derivatives, substituted heterocycles such as substituted pyridines, pyrazines, pyrimidines, pyrrolidinones, substituted and non-substituted N,N-di-C₁₋₂-alkylanilines and other fluorinated or chlorinated aromatics.

A preferred solvent for depositing a compound or polymer according to the present invention by ink jet printing comprises a benzene derivative which has a benzene ring substituted by one or more substituents wherein the total number of carbon atoms among the one or more substituents is at least three. For example, the benzene derivative may be substituted with a propyl group or three methyl groups, in either case there being at least three carbon atoms in total. Such a solvent enables an ink jet fluid to be formed comprising the solvent with the compound or polymer, which reduces or prevents clogging of the jets and separation of the components during spraying. The solvent(s) may include those selected from the following list of examples: dodecylbenzene, 1-methyl-4-tert-butylbenzene, terpineol, limonene, isodurene, terpinolene, cymene, diethylbenzene. The solvent may be a solvent mixture, that is a combination of two or more solvents, each solvent preferably having a boiling point >100° C., more preferably >140° C. Such solvent(s) also enhance film formation in the layer deposited and reduce defects in the layer.

The ink jet fluid (that is mixture of solvent, binder and semiconducting compound) preferably has a viscosity at 20° C. of 1-100 mPa·s, more preferably 1-50 mPa·s and most preferably 1-30 mPa·s.

The polymer blends and formulations according to the present invention can additionally comprise one or more further components or additives selected for example from surface-active compounds, lubricating agents, wetting agents, dispersing agents, hydrophobing agents, adhesive agents, flow improvers, defoaming agents, deaerators, diluents which may be reactive or non-reactive, auxiliaries, colourants, dyes or pigments, sensitizers, stabilizers, nanoparticles or inhibitors.

The compounds and polymers to the present invention are useful as charge transport, semiconducting, electrically conducting, photoconducting or light emitting materials in optical, electrooptical, electronic, electroluminescent or photoluminescent components or devices. In these devices, the polymers of the present invention are typically applied as thin layers or films.

Thus, the present invention also provides the use of the semiconducting compound, polymer, polymers blend, formulation or layer in an electronic device. The formulation may be used as a high mobility semiconducting material in various devices and apparatus. The formulation may be used, for example, in the form of a semiconducting layer or film. Accordingly, in another aspect, the present invention provides a semiconducting layer for use in an electronic device, the layer comprising a compound, polymer, polymer blend or formulation according to the invention. The layer or film may be less than about 30 microns. For various electronic device applications, the thickness may be less than about 1 micron thick. The layer may be deposited, for example on a part of an electronic device, by any of the aforementioned solution coating or printing techniques.

The invention additionally provides an electronic device comprising a compound, polymer, polymer blend, formulation or organic semiconducting layer according to the present invention. Especially preferred devices are OFETs, TFTs, ICs, logic circuits, capacitors, RFID tags, OLEDs, OLETs, OPEDs, OPVs, OPDs, solar cells, laser diodes, photoconductors, photodetectors, electrophotographic devices, electrophotographic recording devices, organic memory devices, sensor devices, charge injection layers, Schottky diodes, planarising layers, antistatic films, conducting substrates and conducting patterns.

Especially preferred electronic device are OFETs, OLEDs, OPV and OPD devices, in particular bulk heterojunction (BHJ) OPV devices. In an OFET, for example, the active semiconductor channel between the drain and source may comprise the layer of the invention. As another example, in an OLED device, the charge (hole or electron) injection or transport layer may comprise the layer of the invention.

For use in OPV or OPD devices the polymer according to the present invention is preferably used in a formulation that comprises or contains, more preferably consists essentially of, very preferably exclusively of, a p-type (electron donor) semiconductor and an n-type (electron acceptor) semiconductor. The p-type semiconductor is constituted by a polymer according to the present invention. The n-type semiconductor can be an inorganic material such as zinc oxide (ZnOₓ), zinc tin oxide (ZTO), titan oxide (TiOₓ), molybdenum oxide (MoOₓ), nickel oxide (NiOₓ), or cadmium selenide (CdSe), or an organic material such as graphene, carbon nanotube or an unsubstituted fullerene or substituted fullerene, for example an unsubstituted C₆₀, an indene-C₆₀-fullerene bisaduct like ICBA-C₆₀, or a (6,6)-phenyl-butyric acid methyl ester derivatized methano C₆₀ fullerene, also known as “PCBM-C₆₀” or “C₆₀PCBM”, as disclosed for example in G. Yu, J. Gao, J. C. Hummelen, F. Wudl, A. J. Heeger, Science 1995, Vol. 270, p. 1789 ff, having the structures shown below, or structural analogous compounds with e.g. a C₆₁ fullerene group, a C₇₀ fullerene group, or a C₇₁ fullerene group, or an organic polymer (see for example Coakley, K. M. and McGehee, M. D. Chem. Mater. 2004, 16, 4533). The n-type semiconductor can also be composed of a combination of the above organic and/or inorganic materials.

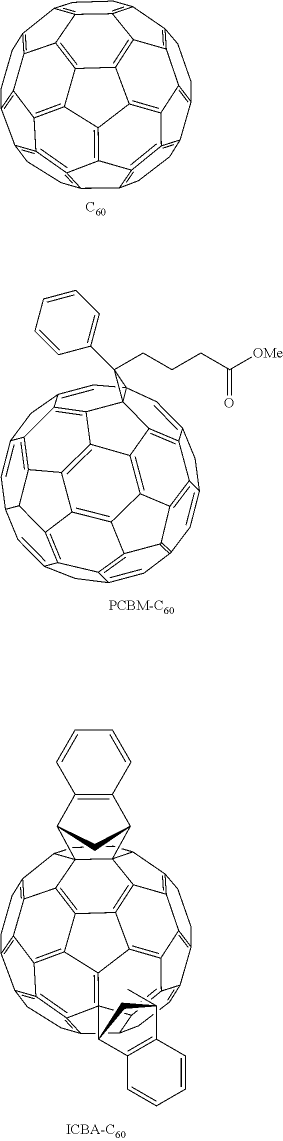

Preferably the polymer according to the present invention is blended with an n-type semiconductor such as a fullerene or substituted fullerene of formula XI to form the active layer in an OPV or OPD device wherein,

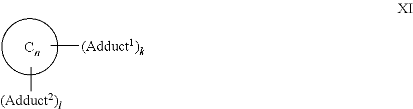

Cₙ denotes a fullerene composed of n carbon atoms, optionally with one or more atoms trapped inside,
Adduct¹ is a primary adduct appended to the fullerene Cₙ with any connectivity,

Adduct² is a secondary adduct, or a combination of secondary adducts, appended to the fullerene Cₙ with any connectivity,
k is an integer 1,
and
l is 0, an integer ≧1, or a non-integer >0.

In the formula XI and its subformulae, k preferably denotes 1, 2, 3 or, 4, very preferably 1 or 2.

The fullerene Cₙ in formula XI and its subformulae may be composed of any number n of carbon atoms Preferably, in the compounds of formula XI and its subformulae the number of carbon atoms n of which the fullerene Cₙ is composed is 60, 70, 76, 78, 82, 84, 90, 94 or 96, very preferably 60 or 70.

The fullerene Cₙ in formula XI and its subformulae is preferably selected from carbon based fullerenes, endohedral fullerenes, or mixtures thereof, very preferably from carbon based fullerenes.

Suitable and preferred carbon based fullerenes include, without limitation, (C₆₀₋ₗₕ)[5,6]fullerene, (C_{70-D5h})[5,6]fullerene, (C_{76-D2*})[5,6]fullerene, (C_{84-D2*})[5,6]fullerene, (C_{84-D2d})[5,6]fullerene, or a mixture of two or more of the aforementioned carbon based fullerenes.

The endohedral fullerenes are preferably metallofullerenes. Suitable and preferred metallofullerenes include, without limitation, La@C₆₀, La@C₈₂, Y@C₈₂, Sc₃N@C₈₀, Y₃N@C₈₀, Sc₃C₂@C₈₀ or a mixture of two or more of the aforementioned metallofullerenes.

Preferably the fullerene Cₙ is substituted at a [6,6] and/or [5,6] bond, preferably substituted on at least one [6,6] bond.

Primary and secondary adduct, named “Adduct” in formula XI and its subformulae, is preferably selected from the following formulae

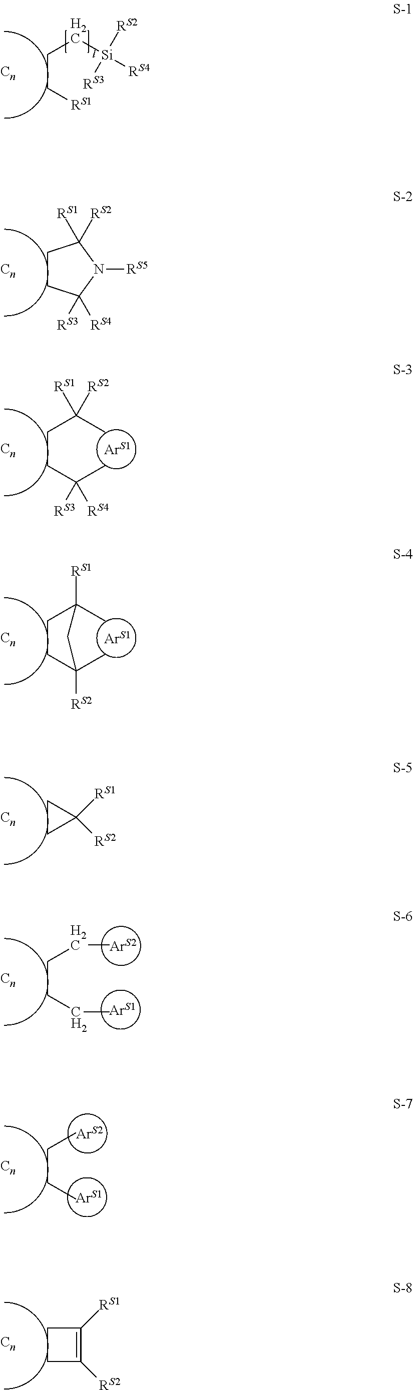

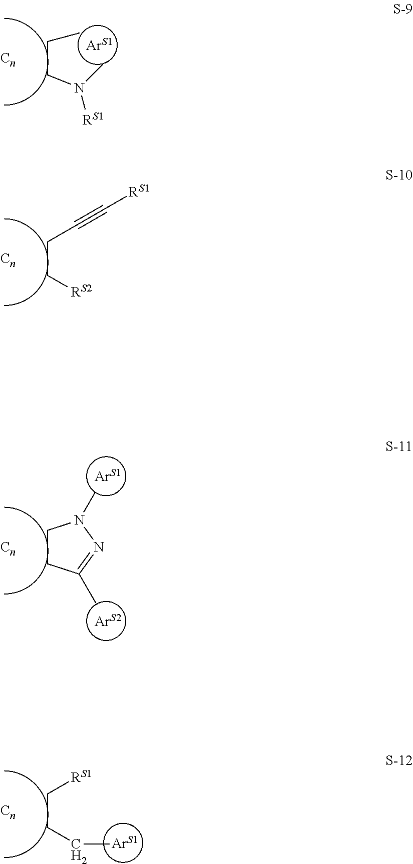

wherein
Ar^{S1}, Ar^{S2} denote, independently of each other, an aryl or heteroaryl group with 5 to 20, preferably 5 to 15, ring atoms, which is mono- or polycyclic, and which is optionally substituted by one or more identical or different substituents having one of the meanings of R^{S} as defined above and below,
   R^{S1}, R^{S2}, R^{S3}, R^{S4} and R^{S5} independently of each other denote H, CN or have one of the meanings of R^{S} as defined above and below.

Preferred compounds of formula XI are selected from the following subformulae:

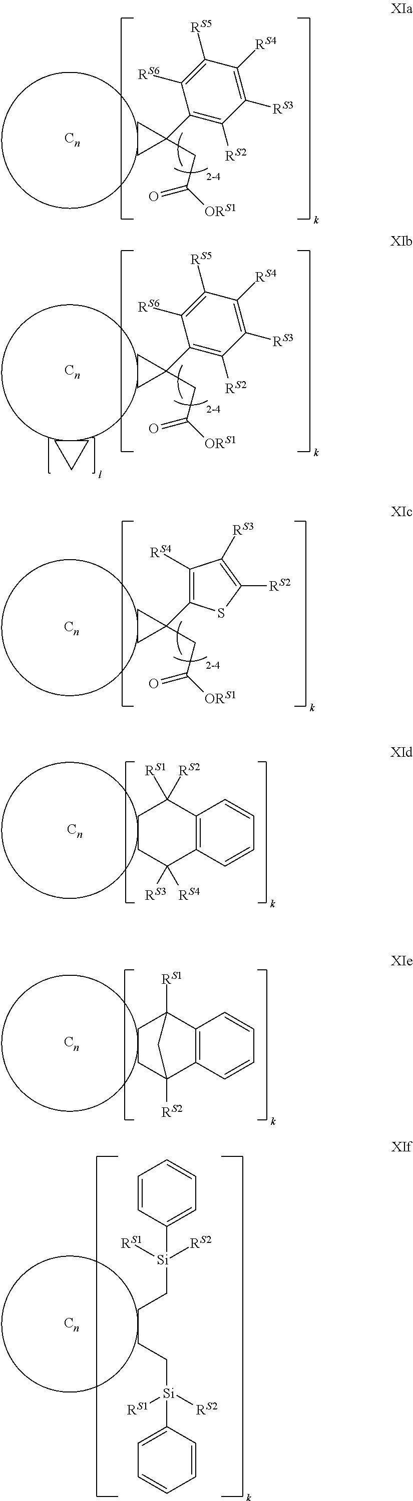

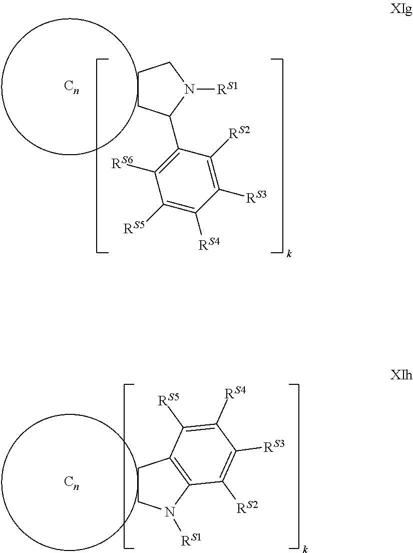

wherein
R^{S1}, R^{S2}, R^{S3}, R^{S4}, R^{S5} and R^{S6} independently of each other denote H or have one of the meanings of R^{S} as defined above and below.

Also preferably the polymer according to the present invention is blended with other type of n-type semiconductor such as graphene, a metal oxide, like for example, ZnOx, TiOx, ZTO, MoOx, NiOx, quantum dots, like for example, CdSe or CdS, or a conjugated polymer, like for example a polynaphthalenediimide or polyperylenediimide as described, for example, in WO2013142841 A1 to form the active layer in an OPV or OPD device.

The device preferably further comprises a first transparent or semi-transparent electrode on a transparent or semi-transparent substrate on one side of the active layer, and a second metallic or semi-transparent electrode on the other side of the active layer.

Preferably, the active layer according to the present invention is further blended with additional organic and inorganic compounds to enhance the device properties. For example, metal particles such as Au or Ag nanoparticules or Au or Ag nanoprism for enhancements in light harvesting due to near-field effects (i.e. plasmonic effect) as described, for example in Adv. Mater. 2013, 25 (17), 2385-2396 and Adv. Ener. Mater. 10.1002/aenm.201400206, a molecular dopant such as 2,3,5,6-tetrafluoro-7,7,8,8-tetracyanoquinodimethane for enhancement in photoconductivity as described, for example in Adv. Mater. 2013, 25(48), 7038-7044, or a stabilising agent consisting of a UV absorption agent and/or anti-radical agent and/or antioxidant agent such as 2-hydroxybenzophenone, 2-hydroxyphenylbenzotriazole, oxalic acid anilides, hydroxyphenyl triazines, merocyanines, hindered phenol, N-aryl-thiomorpholine, N-aryl-thiomorpholine-1-oxide, N-aryl-thiomorpholine-1,1-dioxide, N-aryl-thiazolidine, N-aryl-thiazolidine-1-oxide, N-aryl-thiazolidine-1,1-dioxide and 1,4-diazabicyclo[2.2.2]octane as described, for example, in WO2012095796 A1 and in WO2013021971 A1.

The device preferably may further comprise a UV to visible photo-conversion layer such as described, for example, in J. Mater. Chem. 2011, 21, 12331 or a NIR to visible or IR to NIR photo-conversion layer such as described, for example, in J. Appl. Phys. 2013, 113, 124509.

Further preferably the OPV or OPD device comprises, between the active layer and the first or second electrode, one or more additional buffer layers acting as hole transporting layer and/or electron blocking layer, which comprise a material such as metal oxides, like for example, ZTO, MoOₓ, NiOₓ, a doped conjugated polymer, like for example PEDOT:PSS and polypyrrole-polystyrene sulfonate (PPy:PSS), a conjugated polymer, like for example polytriarylamine (PTAA), an organic compound, like for example substituted triaryl amine derivatives such as N,N′-diphenyl-N,N′-bis(1-naphthyl)(1,1′-biphenyl)-4,4′diamine (NPB), N,N′-diphenyl-N,N′-(3-methylphenyl)-1,1′-biphenyl-4,4′-diamine (TPD), graphene based materials, like for example, graphene oxide and graphene quantum dots or alternatively as hole blocking layer and/or electron transporting layer, which comprise a material such as metal oxide, like for example, ZnOₓ, TiOₓ, AZO (aluminium doped zinc oxide), a salt, like for example LiF, NaF, CsF, a conjugated polymer electrolyte, like for example poly[3-(6-trimethylammoniumhexyl)thiophene], poly(9,9-bis(2-ethylhexyl)-fluorene]-b-poly[3-(6-trimethylammoniumhexyl)thiophene], or poly[(9,9-bis(3′-(N,N-dimethylamino)propyl)-2,7-fluorene)-alt-2,7-(9,9-dioctylfluorene)], a polymer, like for example poly(ethyleneimine) or crosslinked N-containing compound derivatives or an organic compound, like for example tris(8-quinolinolato)-aluminium(III) (Alq₃), phenanthroline derivative or C₆₀ or C₇₀ based fullerenes, like for example, as described in Adv. Energy Mater. 2012, 2, 82-86.

In a blend or mixture of a polymer according to the present invention with a fullerene or modified fullerene, the ratio polymer:fullerene is preferably from 5:1 to 1:5 by weight, more preferably from 1:1 to 1:3 by weight, most preferably 1:1 to 1:2 by weight. A polymeric binder may also be included, from 1 to 99% by weight. Examples of binder include polystyrene (PS), polypropylene (PP) and polymethylmethacrylate (PMMA).

To produce thin layers in BHJ OPV devices the compounds, polymers, polymer blends or formulations of the present invention may be deposited by any suitable method. Liquid coating of devices is more desirable than vacuum deposition techniques. Solution deposition methods are especially preferred. The formulations of the present invention enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing. For the fabrication of OPV devices and modules area printing method compatible with flexible substrates are preferred, for example slot dye coating, spray coating and the like.

Suitable solutions or formulations containing the blend or mixture of a polymer according to the present invention with a C₆₀ or C₇₀ fullerene or modified fullerene like PCBM must be prepared. In the preparation of formulations, suitable solvent must be selected to ensure full dissolution of both component, p-type and n-type and take into account the boundary conditions (for example rheological properties) introduced by the chosen printing method.

Organic solvent are generally used for this purpose. Typical solvents can be aromatic solvents, halogenated solvents or chlorinated solvents, including chlorinated aromatic solvents. Examples include, but are not limited to chlorobenzene, 1,2-dichlorobenzene, chloroform, 1,2-dichloroethane, dichloromethane, carbon tetrachloride, toluene, cyclohexanone, ethylacetate, tetrahydrofuran, anisole, morpholine, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, dimethylformamide, dimethylacetamide, dimethylsulfoxide, tetraline, decaline, indane, methyl benzoate, ethyl benzoate, mesitylene and combinations thereof.

The OPV device can for example be of any type known from the literature (see e.g. Waldauf et al., Appl. Phys. Lett., 2006, 89, 233517).

A first preferred OPV device according to the invention comprises the following layers (in the sequence from bottom to top):
optionally a substrate,
a high work function electrode, preferably comprising a metal oxide, like for example ITO, serving as anode,
an optional conducting polymer layer or hole transport layer, preferably comprising an organic polymer or polymer blend, for example of PEDOT:PSS (poly(3,4-ethylenedioxythiophene):poly(styrene-sulfonate), or TBD (N,N′-dyphenyl-N—N′-bis(3-methylphenyl)-1,1′biphenyl-4,4′-diamine) or NBD (N,N′-dyphenyl-N—N′-bis(1-napthylphenyl)-1,1′biphenyl-4,4′-diamine),
a layer, also referred to as “active layer”, comprising a p-type and an n-type organic semiconductor, which can exist for example as a p-type/n-type bilayer or as distinct p-type and n-type layers, or as blend or p-type and n-type semiconductor, forming a BHJ,
optionally a layer having electron transport properties, for example comprising LiF,
a low work function electrode, preferably comprising a metal like for example aluminum, serving as cathode,
wherein at least one of the electrodes, preferably the anode, is transparent to visible light, and
wherein the p-type semiconductor is a polymer according to the present invention.

A second preferred OPV device according to the invention is an inverted OPV device and comprises the following layers (in the sequence from bottom to top):
optionally a substrate,
a high work function metal or metal oxide electrode, comprising for example ITO, serving as cathode,
a layer having hole blocking properties, preferably comprising a metal oxide like TiOₓ or Znₓ,
an active layer comprising a p-type and an n-type organic semiconductor, situated between the electrodes, which can exist for example as a p-type/n-type bilayer or as distinct p-type and n-type layers, or as blend or p-type and n-type semiconductor, forming a BHJ,
an optional conducting polymer layer or hole transport layer, preferably comprising an organic polymer or polymer blend, for example of PEDOT:PSS or TBD or NBD,
an electrode comprising a high work function metal like for example silver, serving as anode,
wherein at least one of the electrodes, preferably the cathode, is transparent to visible light, and
wherein the p-type semiconductor is a polymer according to the present invention.

In the OPV devices of the present invention the p-type and n-type semiconductor materials are preferably selected from the materials, like the polymer/fullerene systems, as described above.

When the active layer is deposited on the substrate, it forms a BHJ that phase separates at nanoscale level. For discussion on nanoscale phase separation see Dennler et al, Proceedings of the IEEE, 2005, 93 (8), 1429 or Hoppe et al, Adv. Func. Mater, 2004, 14(10), 1005. An optional annealing step may be then necessary to optimize blend morpohology and consequently OPV device performance.

Another method to optimize device performance is to prepare formulations for the fabrication of OPV(BHJ) devices that may include high boiling point additives to promote phase separation in the right way. 1,8-Octanedithiol, 1,8-diiodooctane, nitrobenzene, chloronaphthalene, and other additives have been used to obtain high-efficiency solar cells. Examples are disclosed in J. Peet, et al, Nat. Mater., 2007, 6, 497 or Fréchet et al. J. Am. Chem. Soc., 2010, 132, 7595-7597.

The compounds, polymers, formulations and layers of the present invention are also suitable for use in an OFET as the semiconducting channel. Accordingly, the invention also provides an OFET comprising a gate electrode, an insulating (or gate insulator) layer, a source electrode, a drain electrode and an organic semiconducting channel connecting the source and drain electrodes, wherein the organic semiconducting channel comprises a compound, polymer, polymer blend, formulation or organic semiconducting layer according to the present invention. Other features of the OFET are well known to those skilled in the art.

OFETs where an OSC material is arranged as a thin film between a gate dielectric and a drain and a source electrode, are generally known, and are described for example in U.S. Pat. No. 5,892,244, U.S. Pat. No. 5,998,804, U.S. Pat. No. 6,723,394 and in the references cited in the background section. Due to the advantages, like low cost production using the solubility properties of the compounds according to the invention and thus the processibility of large surfaces, preferred applications of these FETs are such as integrated circuitry, TFT displays and security applications.

The gate, source and drain electrodes and the insulating and semiconducting layer in the OFET device may be arranged in any sequence, provided that the source and drain electrode are separated from the gate electrode by the insulating layer, the gate electrode and the semiconductor layer both contact the insulating layer, and the source electrode and the drain electrode both contact the semiconducting layer.

An OFET device according to the present invention preferably comprises:
a source electrode,
a drain electrode,
a gate electrode,
a semiconducting layer,
one or more gate insulator layers,
optionally a substrate.
   wherein the semiconductor layer preferably comprises a compound, polymer, polymer blend or formulation as described above and below.

The OFET device can be a top gate device or a bottom gate device. Suitable structures and manufacturing methods of an OFET device are known to the skilled in the art and are described in the literature, for example in US 2007/0102696 A1.

The gate insulator layer preferably comprises a fluoropolymer, like e.g. the commercially available Cytop 809M® or Cytop 107M® (from Asahi Glass). Preferably the gate insulator layer is deposited, e.g. by spin-coating, doctor blading, wire bar coating, spray or dip coating or other known methods, from a formulation comprising an insulator material and one or more solvents with one or more fluoro atoms (fluorosolvents), preferably a perfluorosolvent. A suitable perfluorosolvent is e.g. FC75® (available from Acros, catalogue number 12380). Other suitable fluoropolymers and fluorosolvents are known in prior art, like for example the perfluoropolymers Teflon AF® 1600 or 2400 (from DuPont) or Fluoropel® (from Cytonix) or the perfluorosolvent FC 43® (Acros, No. 12377). Especially preferred are organic dielectric materials having a low permittivity (or dielectric constant) from 1.0 to 5.0, very preferably from 1.8 to 4.0 (“low k materials”), as disclosed for example in US 2007/0102696 A1 or U.S. Pat. No. 7,095,044.

In security applications, OFETs and other devices with semiconducting materials according to the present invention, like transistors or diodes, can be used for RFID tags or security markings to authenticate and prevent counterfeiting of documents of value like banknotes, credit cards or ID cards, national ID documents, licenses or any product with monetry value, like stamps, tickets, shares, cheques etc.

Alternatively, the materials according to the invention can be used in OLEDs, e.g. as the active display material in a flat panel display applications, or as backlight of a flat panel display like e.g. a liquid crystal display. Common OLEDs are realized using multilayer structures. An emission layer is generally sandwiched between one or more electron-transport and/or hole-transport layers. By applying an electric voltage electrons and holes as charge carriers move towards the emission layer where their recombination leads to the excitation and hence luminescence of the lumophor units contained in the emission layer. The inventive compounds, materials and films may be employed in one or more of the charge transport layers and/or in the emission layer, corresponding to their electrical and/or optical properties. Furthermore their use within the emission layer is especially advantageous, if the compounds, materials and films according to the invention show electroluminescent properties themselves or comprise electroluminescent groups or compounds. The selection, characterization as well as the processing of suitable monomeric, oligomeric and polymeric compounds or materials for the use in OLEDs is generally known by a person skilled in the art, see, e.g., Müller et al, Synth. Metals, 2000, 111-112, 31-34, Alcala, J. Appl. Phys., 2000, 88, 7124-7128 and the literature cited therein.

According to another use, the materials according to this invention, especially those showing photoluminescent properties, may be employed as materials of light sources, e.g. in display devices, as described in EP 0 889 350 A1 or by C. Weder et al., Science, 1998, 279, 835-837.

A further aspect of the invention relates to both the oxidised and reduced form of the compounds according to this invention. Either loss or gain of electrons results in formation of a highly delocalised ionic form, which is of high conductivity. This can occur on exposure to common dopants. Suitable dopants and methods of doping are known to those skilled in the art, e.g. from EP 0 528 662, U.S. Pat. No. 5,198,153 or WO 96/21659.

The doping process typically implies treatment of the semiconductor material with an oxidating or reducing agent in a redox reaction to form delocalised ionic centres in the material, with the corresponding counterions derived from the applied dopants. Suitable doping methods comprise for example exposure to a doping vapor in the atmospheric pressure or at a reduced pressure, electrochemical doping in a solution containing a dopant, bringing a dopant into contact with the semiconductor material to be thermally diffused, and ion-implantantion of the dopant into the semiconductor material.

When electrons are used as carriers, suitable dopants are for example halogens (e.g., I₂, Cl₂, Br₂, ICl, ICl₃, IBr and IF), Lewis acids (e.g., PF₅, AsF₅, SbF₅, BF₃, BCI₃, SbCl₅, BBr₃ and SO₃), protonic acids, organic acids, or amino acids (e.g., HF, HCl, HNO₃, H₂SO₄, HCIO₄, FSO₃H and ClSO₃H), transition metal compounds (e.g., FeCl₃, FeOCl, Fe(ClO₄)₃, Fe(4-CH₃C₆H₄SO₃)₃, TiCl₄, ZrCl₄, HfCl₄, NbF₅, NbCl₅, TaCl₅, MoF₅, MoCl₅, WF₅, WCl₆, UF₆ and LnCl₃ (wherein Ln is a lanthanoid), anions (e.g., Br⁻, I⁻, I₃⁻, HsO₄⁻, SO₄²⁻, NO₃⁻, ClO₄⁻, BF₄⁻, PF₆⁻, AsF₆⁻, SbF₆⁻, Fe(CN)₆³⁻, and anions of various sulfonic acids, such as aryl-SO₃⁻). When holes are used as carriers, examples of dopants are cations (e.g., H⁺, Li⁺, Na⁺, K⁺, Rb⁺ and Cs⁺), alkali metals (e.g., Li, Na, K, Rb, and Cs), alkaline-earth metals (e.g., Ca, Sr, and Ba), O₂, XeOF₄, (NO₂⁺) (SbF₆⁻), (NO₂⁺) (SbCl₆⁻), (NO₂⁺) (BF₄⁻), AgClO₄, H₂IrCl₆, La(NO₃)₃.6H₂O, FSO₂OOSO₂F, Eu, acetylcholine, R₄N⁺, (R is an alkyl group), R₄P⁺ (R is an alkyl group), R₆As⁺ (R is an alkyl group), and R₃S⁺ (R is an alkyl group).

The conducting form of the compounds of the present invention can be used as an organic “metal” in applications including, but not limited to, charge injection layers and ITO planarising layers in OLED applications, films for flat panel displays and touch screens, antistatic films, printed conductive substrates, patterns or tracts in electronic applications such as printed circuit boards and condensers.

The compounds and formulations according to the present invention may also be suitable for use in organic plasmon-emitting diodes (OPEDs), as described for example in Koller et al., Nat. Photonics, 2008, 2, 684.

According to another use, the materials according to the present invention can be used alone or together with other materials in or as alignment layers in LCD or OLED devices, as described for example in US 2003/0021913. The use of charge transport compounds according to the present invention can increase the electrical conductivity of the alignment layer. When used in an LCD, this increased electrical conductivity can reduce adverse residual dc effects in the switchable LCD cell and suppress image sticking or, for example in ferroelectric LCDs, reduce the residual charge produced by the switching of the spontaneous polarisation charge of the ferroelectric LCs. When used in an OLED device comprising a light emitting material provided onto the alignment layer, this increased electrical conductivity can enhance the electroluminescence of the light emitting material. The compounds or materials according to the present invention having mesogenic or liquid crystalline properties can form oriented anisotropic films as described above, which are especially useful as alignment layers to induce or enhance alignment in a liquid crystal medium provided onto said anisotropic film. The materials according to the present invention may also be combined with photoisomerisable compounds and/or chromophores for use in or as photoalignment layers, as described in US 2003/0021913 A1.

According to another use the materials according to the present invention, especially their water-soluble derivatives (for example with polar or ionic side groups) or ionically doped forms, can be employed as chemical sensors or materials for detecting and discriminating DNA sequences. Such uses are described for example in L. Chen, D. W. McBranch, H. Wang, R. Helgeson, F. Wudl and D. G. Whitten, Proc. Natl. Acad. Sci. U.S.A., 1999, 96, 12287; D. Wang, X. Gong, P. S. Heeger, F. Rininsland, G. C. Bazan and A. J. Heeger, Proc. Natl. Acad. Sci. U.S.A., 2002, 99, 49; N. DiCesare, M. R. Pinot, K. S. Schanze and J. R. Lakowicz, Langmuir, 2002, 18, 7785; D. T. McQuade, A. E. Pullen, T. M. Swager, Chem. Rev., 2000, 100, 2537.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

Above and below, unless stated otherwise percentages are percent by weight and temperatures are given in degrees Celsius. The values of the dielectric constant ∈ (“permittivity”) refer to values taken at 20° C. and 1,000 Hz.

The invention will now be described in more detail by reference to the following examples, which are illustrative only and do not limit the scope of the invention.

### Example 1

Poly{7,7-bis-(2-ethyl-hexyl)-3,4-dithia-7-sila-cyclopenta[a]pentalene}-alt-2,3,7,8-tetramethyl-pyrazino[2,3-g]quinoxaline P1 was prepared as follows:

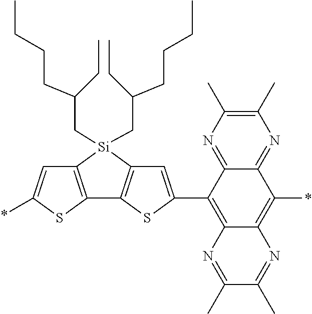 [SMILES: *c1cc2c(s1)-c1sc(-c3c4nc(C)c(C)nc4c(*)c4nc(C)c(C)nc34)cc1[Si]2(CC(CC)CCCC)CC(CC)CCCC]

### 1a) 5,10-Dibromo-2,3,7,8-tetramethyl-pyrazino[2,3-g]quinoxaline

A suspension of 4,7-dibromo-5,6-dinitro-benzo[1,2,5]thiadiazole (2.30 g, 5.99 mmol) and zinc (11.90 g, 181.99 mmol) in acetic acid (240 cm³) and water (1 cm³) is heated at 60° C. for 2 hours, cooled to 23° C. and filtered to remove solids. To the filtrate is added butane-2,3-dione (2.04 cm³, 23.23 mmol) and the reaction mixture is stirred at 23° C. for 3.5 days. The solvent is removed in vacuo and the crude purified by column chromatography (eluent: chloroform then 3% methanol in chloroform) to yield a yellow solid. The solid is recrystallised from acetonitrile/tetrahydrofuran to yield a yellow powder which is purified by column chromatography (eluent: 25% ethyl acetate in chloroform) to yield a yellow solid which is triturated with methanol. The solid is collected by filtration to yield the product as a yellow powdery solid (180 mg, 8%).

¹H NMR (300 MHz, CDCl₃, ppm) 2.91 (s, 12H, CH₃).

### 1b) Poly{7,7-bis-(2-ethyl-hexyl)-3,4-dithia-7-sila-cyclopenta[a]pentalene}-alt-2,3,7,8-tetramethyl-pyrazino[2,3-g]quinoxaline P1

5,10-Dibromo-2,3,7,8-tetramethyl-pyrazino[2,3-g]quinoxaline (108.1 mg, 0.273 mmol), 7,7-bis-(2-ethyl-hexyl)-2,5-bis-trimethylstannanyl-7H-3,4-dithia-7-sila-cyclopenta[a]pentalene (203.2 mg, 0.273 mmol), tri-o-tolyl-phosphine (13.3 mg, 0.043 mmol) and tris(dibenzyl-ideneacetone)-dipalladium(0) (10.0 mg, 0.010 mmol) are weighed into a flask and vacuum/nitrogen purged ×3. Degassed chlorobenzene (3.4 cm³) is added and the mixture further purged with nitrogen for 15 minutes. The reaction mixture is heated to 140° C. for 3 hours 25 minutes with a preheated oil bath and stirring at 500 rpm. The reaction mixture is allowed to cool to about 65° C. and the solution poured into methanol (75 cm³) with methanol washings (3×10 cm³) of the reaction flask. The polymer is collected by filtration and washed with methanol (2×50 cm³) to give a black solid. The polymer is washed via Soxhlet extraction with acetone, petrol (40-60), cyclohexane and chloroform. The chloroform fraction is precipitated into stirred methanol (100 cm³). The polymer is collected by filtration, washed with methanol (50 cm³) and vacuum dried to yield the product as a black solid (140 mg, 79%). GPC (50° C., chlorobenzene): Mₙ=17.0 kg·mol⁻¹; M_{w}=38.9 kg·mol⁻¹; PDI=2.29.

### Example 2

Poly{7,7-bis-(2-ethyl-hexyl)-3,4-dithia-7-sila-cyclopenta[a]pentalene}-alt-2,3,7,8-tetraphenyl-pyrazino[2,3-g]quinoxaline P2 was prepared as follows:

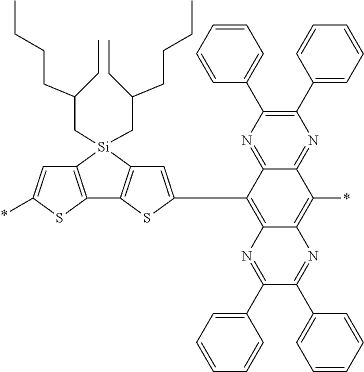 [SMILES: *c1cc2c(s1)-c1sc(-c3c4nc(-c5ccccc5)c(-c5ccccc5)nc4c(*)c4nc(-c5ccccc5)c(-c5ccccc5)nc34)cc1[Si]2(CC(CC)CCCC)CC(CC)CCCC]

### 2a) 2,3,7,8-Tetraphenyl-pyrazino[2,3-c]quinoxaline

To a solution of toluene (12.5 cm³) and pyridine (17.5 cm³) is added benzene-1,2,4,5-tetraamine tetrahydrochloride (1.00 g; 3.52 mmol) and 1,2-diphenyl-ethane-1,2-dione (1.85 g; 8.80 mmol), the reaction mixture is stirred at 25° C. for 48 hours. The reaction mixture is precipitated with the addition of methanol (50 cm³) and the solids are collected by filtration and washed with further methanol to yield the product as a yellow powdery solid (1.31 g, 76%).

¹H NMR (300 MHz, CDCl₃, ppm) 9.04 (s, 2H, CH), 7.63 (dd, J=8.0, 2.0, 8H, ArH), 7.42 (m, 12H, ArH).

### 2b) 5,10-Dibromo-2,3,7,8-tetraphenyl-pyrazino[2,3-c]quinoxaline

To a solution of 2,3,7,8-tetraphenyl-pyrazino[2,3-g]quinoxaline (1.03 g; 2.12 mmol) and sodium hydrogen carbonate (0.36 g; 4.23 mmol) in chloroform (20 cm³) at 0° C. is added bromine (0.22 cm³, 4.23 mmol). The reaction mixture is warmed to 50° C. and stirred at this temperature for 16 hours. Further sodium hydrogen carbonate (0.36 g; 4.23 mmol) and bromine (0.22 cm³, 4.23 mmol) is added and the reaction mixture is heated at 50° C. for 20 hours. Methanol (20 cm³) is added to the reaction mixture and the precipitate is collected by filtration, washed with hot tetrahydrofuran/acetonitrile and dichloromethane and dried to yield the product as a powdery yellow solid (0.90 g, 66%).

### 2c) Poly{7,7-bis-(2-ethyl-hexyl)-3,4-dithia-7-sila-cyclopenta[a]pentalene}-alt-2,3,7,8-tetraphenyl-pyrazino[2,3-o]quinoxaline P2

5,10-Dibromo-2,3,7,8-tetraphenyl-pyrazino[2,3-g]quinoxaline (167.9 mg, 0.261 mmol), 7,7-bis-(2-ethyl-hexyl)-2,5-bis-trimethylstannanyl-7H-3,4-dithia-7-sila-cyclopenta[a]pentalene (200.0 mg, 0.269 mmol), tri-o-tolyl-phosphine (9.8 mg, 0.032 mmol) and tris(dibenzyl-ideneacetone)-dipalladium(0) (4.9 mg, 0.005 mmol) are weighed into a flask and vacuum/nitrogen purged ×3. Degassed toluene (13.0 cm³) is added and the mixture further purged with nitrogen for 10 minutes. The reaction mixture is heated to 100° C. for 16 hours with a preheated oil bath and stirring at 500 rpm. The reaction mixture is allowed to cool to about 65° C. and the solution poured into methanol (100 cm³) with methanol washings (3×10 cm³) of the reaction flask. The polymer is collected by filtration and washed with methanol (2×50 cm³) to give a black solid. The polymer is washed via Soxhlet extraction with acetone, petrol (40-60), cyclohexane and chloroform. The chloroform fraction is precipitated into stirred methanol (100 cm³). The polymer is collected by filtration, washed with methanol (50 cm³) and vacuum dried to yield the product as a black solid (173 mg, 71%). GPC (50° C., chlorobenzene): Mₙ=7.2 kg·mol⁻¹; M_{w}=12.4 kg·mol⁻¹; PDI=1.72.

### Example 3

Poly{7,7-bis-(2-ethyl-hexyl)-3,4-dithia-7-sila-cyclopenta[a]pentalene}-alt-2,3,7,8-tetrakis-(3-octyloxy-phenyl)-pyrazino[2,3-g]quinoxaline P3 was prepared as follows:

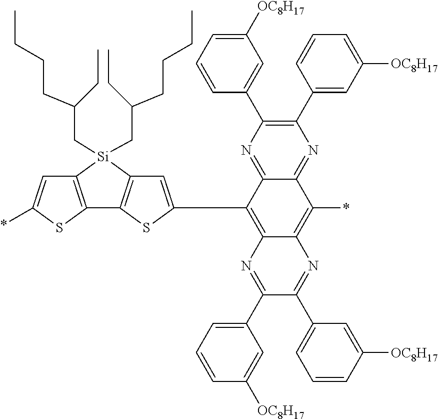

5,10-Dibromo-2,3,7,8-tetrakis-(3-octyloxy-phenyl)-pyrazino[2,3-g]quinoxaline was prepared as described in Org. Lett., 12, 20, 2010, 4470-4473.

5,10-Dibromo-2,3,7,8-tetrakis-(3-octyloxy-phenyl)-pyrazino[2,3-g]quinoxaline (194.3 mg, 0.168 mmol), 7,7-bis-(2-ethyl-hexyl)-2,5-bis-trimethylstannanyl-7H-3,4-dithia-7-sila-cyclopenta[a]pentalene (125.0 mg, 0.168 mmol), tri-o-tolyl-phosphine (6.1 mg, 0.020 mmol) and tris(dibenzyl-ideneacetone)-dipalladium(0) (3.1 mg, 0.003 mmol) are weighed into a flask and vacuum/nitrogen purged ×3. Degassed toluene (8.1 cm³) is added and the mixture further purged with nitrogen for 10 minutes. The reaction mixture is heated to 100° C. for 1 hour and 30 minutes with a preheated oil bath and stirring at 500 rpm, and then to 120° C. for a further 21 hours. The reaction mixture is allowed to cool to about 65° C. and the solution poured into methanol (100 cm³) with methanol washings (3×10 cm³) of the reaction flask. The polymer is collected by filtration and washed with methanol (2×50 cm³) to give a black solid. The polymer is washed via Soxhlet extraction with acetone and petrol (40-60). The petrol (40-60) fraction is concentrated in vacuo and precipitated into stirred methanol (100 cm³). The polymer is collected by filtration, washed with methanol (50 cm³) and vacuum dried to yield the product as a black solid (136 mg, 57%). GPC (50° C., chlorobenzene): Mₙ=18.7 kg·mol⁻¹; M_{w}=26.8 kg·mol⁻¹; PDI=1.43.

### Example 4

### Bulk Heterojunction Organic Photodetector Devices (OPDs) for Polymer P1, P2 and P3

OPD devices are fabricated on ITO substrates that were pre-patterned with dots sized 50 mm. The received ITO glass substrates were cleaned by using a normal glass cleaning procedure: 30 minutes ultrasonic bath in Dycon 90 solution, followed by DI washing 3 times and another 30 minutes ultrasonic bath in DI water.

A layer of Cs₂CO₃+PVP (from a 1% solution in methanol), or ZnO NPs (from a 1% dispersion in ethanol), was deposited at a speed of 2000 rpm for 1 minute and annealed at 100° C. for 10 minutes.

The active layer of Polymer:PC₇₀BM (1:1 or 1:3) (prepared from a solution of 10 mg Polymer and 10 to 30 mg PC₇₀BM in oDCB, where the solution was kept on 70° C. and stirred overnight in a sealed bottle before use) was deposited in sequence by blade coating (K101 Control Coater System) with a substrate temperature of 70° C. The distance between blade and substrate were set to 15-50 μm, and a speed of 0.2 m·min⁻¹. The active layer was annealed at 100° C. for 10 minutes. The thickness is around 500 nm.

A layer of MoO₃ was deposited on top of the active layer using E-beam in vacuum from MoO₃ powder source, the thickness is around 15 nm.

For the final fabrication step, Ag metal electrodes were thermally deposited through a shadow mask, the metal dots matching the bottom ITO dots. The thickness is around 50 nm.

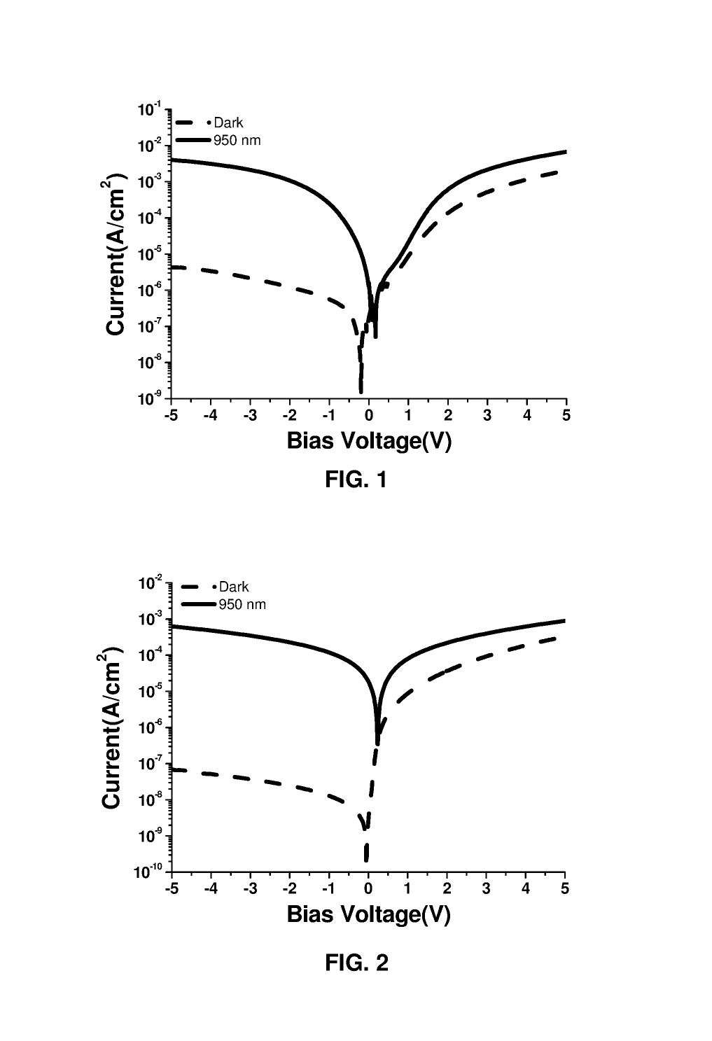

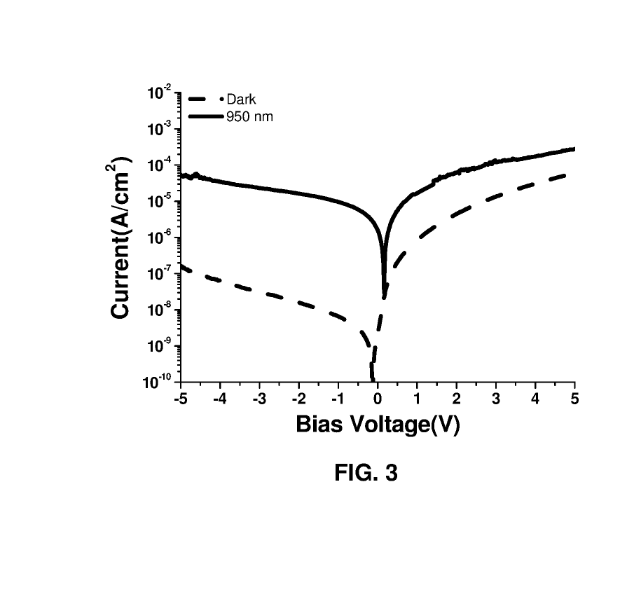

A typical J-V curve for one of the OPD devices with P1 is shown in FIG. 1, a typical J-V curve for one of the OPD devices with P2 is shown in FIG. 2 and a typical J-V curve for one of the OPD devices with P3 is shown in FIG. 3.

1. A polymer comprising one or more units of formula I and one or more units of formula II 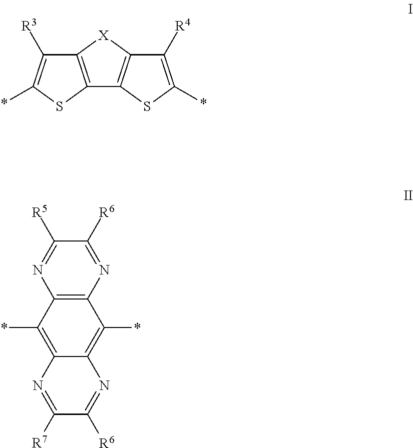
wherein
X is SiR¹R², CR¹R², NR¹ or GeR¹R², and
R¹⁻⁸ independently of each other denote H or a carbyl or hydrocarbyl group with 1 to 40 C atoms that is optionally substituted, wherein at least one of R¹ and R² is different from H and at last one of R³ to R⁸ is different from H.

2. The polymer according to claim 1, wherein in formula I X is Si.

3. The polymer according to claim 1, wherein
in the units of formula I
R³ and R⁴ are H, and
R¹ and R² are each independently a straight-chain or branched alkyl, alkoxy or sulfanylalkyl with 1 to 30 C atoms, or a straight-chain or branched alkylcarbonyl, alkylcarbonyloxy or alkyloxycarbonyl with 2 to 30 C atoms, each of the aforementioned groups being unsubstituted or substituted by one or more F atoms,
and
in the units of formula II
R⁵, R⁶, R⁷ and R⁸ are each independently a straight-chain or branched alkyl, alkoxy or sulfanylalkyl with 1 to 30 C atoms, or a straight-chain or branched alkylcarbonyl, alkylcarbonyloxy or alkyloxycarbonyl with 2 to 30 C atoms, each of the aforementioned groups being unsubstituted or substituted by one or more F atoms.

4. The polymer according to claim 1, wherein
in the units of formula I
R³ and R⁴ are H, and
R¹ and R² are each independently a straight-chain or branched alkyl, alkoxy or sulfanylalkyl with 1 to 30 C atoms, or a straight-chain or branched alkylcarbonyl, alkylcarbonyloxy or alkyloxycarbonyl with 2 to 30 C atoms, each of the aforementioned groups being unsubstituted or substituted by one or more F atoms, or an aryl, heteroaryl, aryloxy or heteroaryloxy, each of which is optionally fluorinated, alkylated or alkoxylated and has 4 to 30 ring atoms
and
in the units of formula II
R⁵, R⁶, R⁷ and R⁸ are each independently an aryl, heteroaryl, aryloxy or heteroaryloxy, each of which is optionally fluorinated, alkylated or alkoxylated and has 4 to 30 ring atoms.

5. The polymer according to claim 1, additionally comprising one or more units selected from arylene and heteroarylene groups that have 5 to 30 ring atoms and are optionally substituted, optionally by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF₅, or an optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀ carbyl or hydrocarbyl, and
X⁰ is halogen.

6. The polymer according to claim 1, which is of formula III:
*-[(D)_{d}-(A)ₐ-(Ar¹)_{b}—(Ar²)_{c}]ₙ—* III
wherein
D is a unit of formula I,
A is a unit of formula II,
Ar¹, Ar² independently of each other denote an arylene or heteroarylene group with 5 to 30 ring atoms that is optionally substituted, optionally by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF₅, or an optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀ carbyl or hydrocarbyl,
X⁰ is halogen,
a, b, c, d are independently of each other 0, 1, 2 or 3, with at least one of a and d being different from 0 in at least one repeating unit, and
n is an integer >1.

7. The polymer according to claim 1, which is of one of the following formulae: 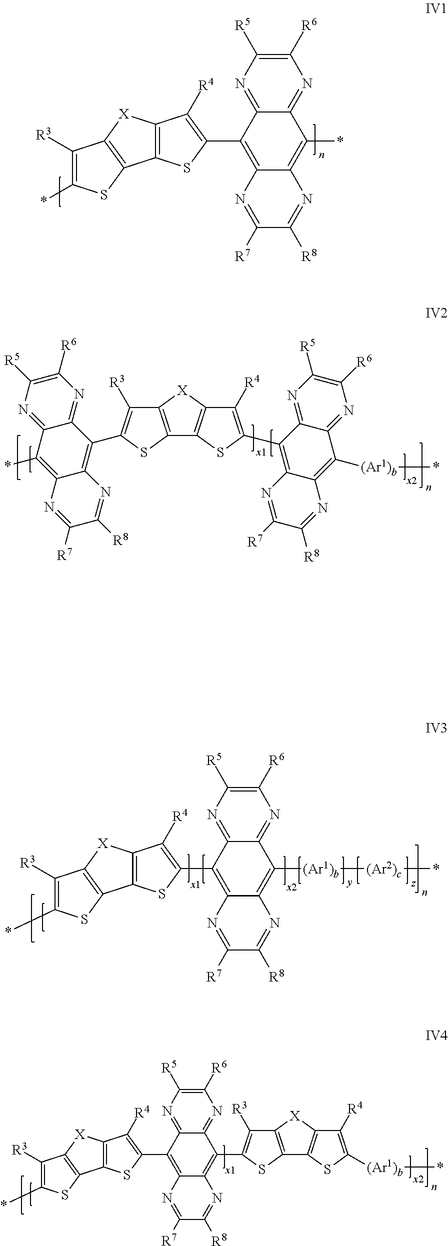
wherein
X is SiR¹R², CR¹R², NR¹ or GeR¹R²,
R¹⁻⁸ independently of each other denote H or a carbyl or hydrocarbyl group with 1 to 40 C atoms that is optionally substituted, wherein at least one of R¹ and R² is different from H and at least one of R³ to R⁸ is different from H,
Ar¹, Ar² independently of each other denote an arylene or heteroarylene group with 5 to 30 ring atoms that is optionally substituted, optionally by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF₅, or an optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀ carbyl or hydrocarbyl,
X⁰ is halogen,
b, c are independently of each other 0, 1, 2 or 3, with at least one of a and d being different from 0 in at least one repeating unit,
n is an integer >1,
x1 is >0 and ≦1,
x2 is >0 and ≦1,
y is ≧0 and <1,
z is ≧0 and <1, and
x1+x2+y+z is 1.

8. The polymer of claim 7, wherein
X is SiR¹R², R³ and
R⁴ are H, and
R¹, R², R⁵, R⁶, R⁷ and R⁸ are each independently a straight-chain or branched alkyl, alkoxy or sulfanylalkyl with 1 to 30 C atoms, or a straight-chain or branched alkylcarbonyl, alkylcarbonyloxy or alkyloxycarbonyl with 2 to 30 C atoms, each of the aforementioned groups being unsubstituted or substituted by one or more F atoms, or an aryl, heteroaryl, aryloxy or heteroaryloxy, each of which is optionally fluorinated, alkylated or alkoxylated and has 4 to 30 ring atoms.

9. The polymer according to claim 1, which is of formula V
R^{T1}-chain-R^{T2} V
wherein
claim is a polymer chain of formulae III or VI1-VI4, 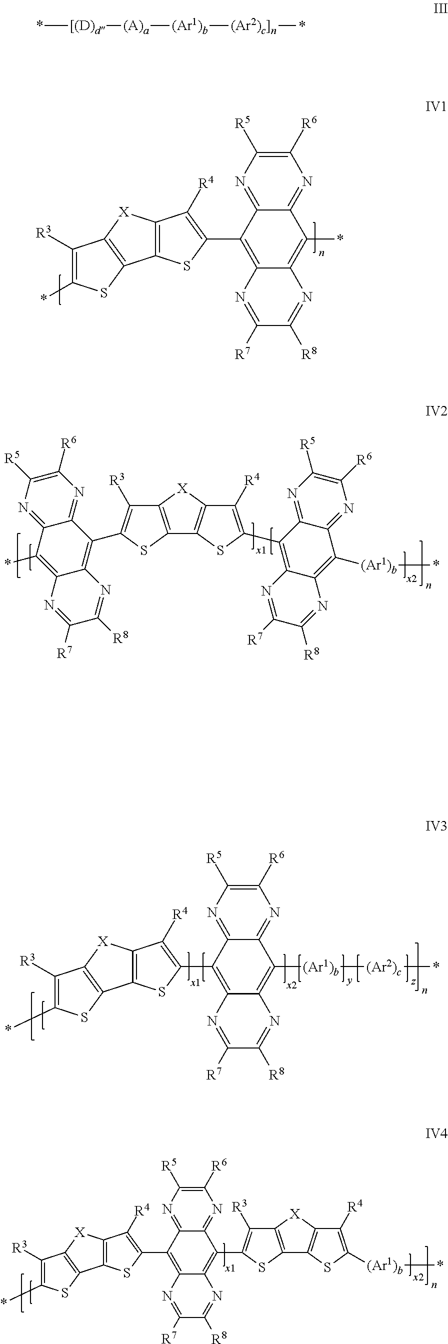
wherein
D is a unit of formula I,
A is a unit of formula II,
Ar¹, Ar² independently of each other denote an arylene or heteroarylene group with 5 to 30 ring atoms that is optionally substituted, optionally by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF₅, or an optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀ carbyl or hydrocarbyl,
X⁰ is halogen,
a, b, c, d are independently of each other 0, 1, 2 or 3, with at least one of a and d being different from 0 in at least one repeating unit,
n is an integer >1,
X is SiR¹R², CR¹R², NR¹ or GeR¹R²,
R¹⁻⁸ independently of each other denote H or a carbyl or hydrocarbyl group with 1 to 40 C atoms that is optionally substituted, wherein at least one of R¹ and R² is different from H and at least one of R³ to R⁸ is different from H,
x1 is >0 and ≦1,
x2 is >0 and ≦1,
y is ≧0 and <1,
z is ≧0 and <1, and
x1+x2+y+z is 1
R^{T1} and R^{T2} have independently of each other one of the meanings of R^{S}, or denote, independently of each other, H, F, Br, Cl, I, —CH₂Cl, —CHO, —CR′═CR″₂, —SiR′R″R′″, —SiR′X′X″, —SiR′R″X′, —SnR′R″R′″, —BR′R″, —B(OR′)(OR″), —B(OH)₂, —O—SO₂—R′, —C≡CH, —C≡C—SiR′₃, —ZnX′, or an endcap group,
X′ and X″ denote halogen,
R′, R″ and R′″ have independently of each other one of the meanings of R⁰, or two of R′, R″ and R′″ form a ring together with the hetero atom to which they are attached.

10. A mixture or polymer blend comprising one or more polymers according claim 1 and one or more compounds or polymers having semiconducting, charge transport, hole/electron transport, hole/electron blocking, electrically conducting, photoconducting or light emitting properties.

11. The mixture or polymer blend according to claim 10, comprising one or more n-type organic semiconductor compounds.

12. The mixture or polymer blend according to claim 11, wherein the n-type organic semiconductor compound is a fullerene or substituted fullerene.

13. A formulation comprising one or more polymers according to claim 1 and one or more solvents, optionally organic solvents.

14. (canceled)

15. A charge transport, semiconducting, electrically conducting, photoconducting or light emitting material comprising a polymer according to claim 1.

16. An optical, electrooptical, electronic, electroluminescent or photoluminescent device, or a component thereof, or an assembly, which comprises a polymer according to claim 1.

17. A device, a component thereof, or an assembly according to claim 16, wherein the device is selected from the group consisting of organic field effect transistors (OFET), thin film transistors (TFT), organic light emitting diodes (OLED), organic light emitting transistors (OLET), organic photovoltaic devices (OPV), organic photodetectors (OPD), organic solar cells, laser diodes, Schottky diodes, and photoconductors, the component is selected from the group consisting of charge injection layers, charge transport layers, interlayers, planarising layers, antistatic films, polymer electrolyte membranes (PEM), conducting substrates, conducting patterns, and the assembly is selected from the group consisting of integrated circuits (IC), radio frequency identification (RFID) tags, security markings, security devices, flat panel displays, backlights of flat panel displays, electrophotographic devices, electrophotographic recording devices, organic memory devices, sensor devices, biosensors and biochips.

18. The device according to claim 17, which is an OFET, bulk heterojunction (BHJ) OPV device or inverted BHJ OPV device.

19. A monomer of formula VI
R^{R1}—(Ar¹)_{b}-(D)_{d}-(Ar²)_{c}-(A)ₐ-(Ar²)_{b}—R^{R2} VI
wherein
D is a unit of formula I,
A is a unit of formula II,
Ar¹, Ar² independently of each other denote an arylene or heteroarylene group with 5 to 30 ring atoms that is optionally substituted, optionally by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF₅, or an optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀ carbyl or hydrocarbyl,
X⁰ is halogen,
b, c, d are independently of each other 0, 1, 2 or 3, with at least one of a and d being different from 0 in at least one repeating unit,
a is 1, 2 or 3, and
R^{R1} and R^{R2} are independently of each other selected from the group consisting of Cl, Br, I, O-tosylate, O-triflate, O-mesylate, O-nonaflate, —SiMe₂F, —SiMeF₂, —O—SO₂Z¹, —B(OZ²)₂, —CZ³═C(Z⁴)₂, —C≡C—Si(Z¹)₃, —ZnX⁰ and —Sn(Z⁴)₃, wherein
X⁰ is halogen, preferably Cl, Br or I,
Z¹⁻⁴ are selected from the group consisting of alkyl and aryl, preferably C₁-C₁₂-alkyl and C₄-C₁₀-aryl, each being optionally substituted, and two groups Z² may also form a cyclic group together with the B- and O-atoms.

20. The monomer according to claim 19, which is one of the following formulae
R^{R1}—Ar¹-D-Ar²-A-R^{R2} VI1
R^{R1}-D-A-R^{R2} VI2
R^{R1}-D-A-R^{R2} VI3
R^{R1}—Ar¹-A-R^{R2} VI4
R_{R1}—Ar₁-A-Aᵣ₂-R_{R2} VI5
wherein D, A, Ar¹, Ar², R^{R1} and R^{R2} are as defined for the monomer of formula VI.

21. A process of preparing a polymer according to claim 1, comprising coupling one or more monomers with each other in an aryl-aryl coupling reaction, which monomers are one or more monomers of the following formulae
R^{R1}—Ar¹-D-Ar²-A-R^{R2} VI1
R^{R1}-D-A-R^{R2} VI2
R^{R1}-A-R^{R2} VI3
R^{R1}—Ar¹-A-R^{R2} VI4
R^{R1}—Ar¹-A-Ar²—R^{R2} VI5
R^{R1}-D-R^{R2} VII
R^{R1}—Ar¹—R^{R2} VIII
R^{R1}—Ar²—R^{R2} IX
wherein
D is a unit of formula I,
A is a unit of formula II,
Ar¹, Ar² independently of each other denote an arylene or heteroarylene group with 5 to 30 ring atoms that is optionally substituted, optionally by one or more groups R^{S},
R^{S} is on each occurrence identically or differently F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —SO₃H, —SO₂R⁰, —OH, —NO₂, —CF₃, —SF₅, or an optionally substituted silyl, carbyl or hydrocarbyl with 1 to 40 C atoms that is optionally substituted and optionally comprises one or more hetero atoms,
R⁰ and R⁰⁰ are independently of each other H or optionally substituted C₁₋₄₀carbyl or hydrocarbyl,
R^{R1} and R^{R2} are each independently Cl, Br, I, —B(OZ²)₂ or —Sn(Z⁴)₃.
